(19) United States
(12) Patent Application Publication
(10) Pub. No.: US 2024/0224814 A1
(43) Pub. Date: Jul. 4, 2024

(54) CHIRAL COUPLING-BASED VALLEYTRONIC MAGNETOELECTRIC SPIN-ORBIT DEVICES

(71) Applicant: Intel Corporation, Santa Clara, CA (US)

(72) Inventors: Punyashloka Debashis, Hillsboro, OR (US); Dmitri Evgenievich Nikonov, Beaverton, OR (US); Ian Alexander Young, Olympia, WA (US); Hai Li, Portland, OR (US)

(73) Assignee: Intel Corporation, Santa Clara, CA (US)

(21) Appl. No.: 18/148,240

(22) Filed: Dec. 29, 2022

(51) Int. Cl. H10N 50/85; G11C 11/16; H01F 10/32; H03K 19/18; H10N 52/80

(52) U.S. Cl. CPC H10N 50/85; G11C 11/161; H01F 10/3286; H03K 19/18; H10N 52/80

(57) ABSTRACT

Valleytronic magnetoelectric spin-orbit (MESO) logic devices comprise a charge-to-spin conversion input module that comprises a magnetoelectric capacitor. The input module converts a differential input voltage into a magnetization orientation of a ferromagnet possessing in-plane anisotropy (IPA) through exchange coupling between the IPA ferromagnet and the magnetoelectric layer of the capacitor. The magnetization orientation of the IPA ferromagnet can represent the logic state of the valleytronic MESO device. A spin-to-charge conversion output module comprises a ferromagnet possessing perpendicular magnetic anisotropy (PMA) and a 2D valleytronic material. The IMA and PMA ferromagnets are chirally-coupled through Dzaloshinskii-Moriya interaction, which causes the perpendicular magnetic orientation of the PMA ferromagnet to switch with the in-plane magnetization orientation of the IPA ferromagnet. The logic state of the device is read through injection of spin-polarized current from the PMA ferromagnet into the 2D valleytronic layer, which converts the injected spin-polarized current into a differential output current.

### BACKGROUND

Magnetoelectric spin-orbit (MESO) logic is a type of spintronic logic that operates using the magnetoelectric effect in conjunction with the spin-orbit coupling effect (e.g., the coupling of an electron's angular momentum with its linear momentum). A MESO device uses magnetoelectric switching to convert an input voltage/charge into a magnetic spin state (e.g., charge-to-spin conversion) and spin-orbit transduction to convert the magnetic spin state into an output charge/voltage (e.g., spin-to-charge conversion).

Numerous materials (even as common as silicon or germanium) have an electronic band structure where the transport of carriers occurs at multiple compact regions of the electron momentum space, called ‘valleys’. Some of these materials possess topological properties. An example of such topological properties are quantum states of electrons with a geometrical phase (e.g., Berry phase) of the wave function accumulated as the parameter (e.g., momentum) of the electron is varied along a loop. Berry phase is exhibited by, for example, topological insulator materials such as Bi₂Se₃. The curvature of the Berry phase in the momentum space functions as a gauge field, or in other words, an effective magnetic field inherent in such materials.

Valleytronic devices, which are an alternative to electronic and spintronic devices, utilize valley-dependent properties of materials to store and/or carry information. Some ferroelectric materials, when sufficiently thin (e.g., in 2D form) possess the properties of energy band splitting into electron-spin dependent sub-bands and Berry curvature dependency on the polarization of the ferroelectric material.

### BRIEF DESCRIPTION OF THE DRAWINGS

FIG. 1 illustrates an example differential magnetoelectric spin-orbit (MESO) logic device.

FIG. 2 illustrates energy band extrema for an example 2D valleytronic layer.

FIG. 3A illustrates a perspective view of a first example valleytronic MESO device.

FIGS. 3B and 3C illustrate cross-sectional views of the first example valleytronic MESO device illustrated in FIG. 3A taken along the lines A-A′ and B-B′, respectively.

FIG. 4A illustrates a perspective view of a second example valleytronic MESO device.

FIGS. 4B and 4C illustrate cross-sectional views of the first example valleytronic MESO device illustrated in FIG. 4A taken along the lines A-A′ and B-B′, respectively.

FIGS. 5A-5N and 6A-6N illustrate cross-sectional views of the example valleytronic device illustrated in FIGS. 3A-3C at various stages of fabrication.

FIG. 7 illustrates a flowchart of an example method for fabricating the valleytronic device illustrated in FIGS. 3A-3C.

FIGS. 8A-8P and 9A-9P illustrate cross-sectional views of the example valleytronic device of FIGS. 4A-4C at various stages of fabrication.

FIG. 10 illustrates a flowchart of an example method for fabricating the valleytronic device illustrated in FIGS. 4A-4C.

FIG. 11 is a top view of a wafer and dies on which any of the valleytronic MESO devices disclosed herein may be fabricated.

FIG. 12 is a cross-sectional side view of an integrated circuit device that may be included in any of the microelectronic assemblies disclosed herein, in accordance with any of the embodiments disclosed herein.

FIGS. 13A-13D are simplified perspective views of example planar, FinFET, gate-all-around, and stacked gate-all-around transistors.

FIG. 14 is a cross-sectional side view of an integrated circuit device assembly that may include any of the microelectronic assemblies comprising any of the valleytronic MESO devices disclosed herein.

FIG. 15 is a block diagram of an example electrical device that may include one or more of the microelectronic assemblies disclosed herein.

### DETAILED DESCRIPTION

Various device types are being examined as alternatives to CMOS (complementary metal-oxide-semiconductor) electronic devices as the scaling of fabrication technologies extends to minimum feature sizes on the scale of ones of nanometers. Spintronic and valleytronic devices are two such device types and utilize electron spin and energy band valley-dependent material properties, respectively, to store and/or carry information.

Magnetoelectric spin-orbit (MESO) devices are one type of spintronic device being examined. MESO devices comprise a magnetoelectric switching capacitor coupled to a spin-to-charge conversion output module. The magnetoelectric capacitor comprises a magnetoelectric layer positioned between a ferromagnet and another electrode. The logic state of the MESO device is represented by the magnetization orientation of the ferromagnet and can be set through application of a voltage across the magnetoelectric capacitor. The magnetoelectric layer's ferroelectric polarization couples with its antiferromagnetic order and, upon application of the proper input voltage polarity, causes the canted magnetization of the magnetoelectric layer to flip. The magnetoelectric layer and the ferromagnetic layer of the magnetoelectric capacitor are coupled via magnetic exchange and the switching of the antiferromagnetic order, as well as the canted magnetization orientation of the magnetoelectric layer, induces switching of the magnetization orientation of the ferromagnetic layer. The magnetization state of the ferromagnet, and hence, the logic state of the MESO device, is read out by the spin-to-charge conversion output module, which converts the ferromagnet magnetization orientation to an output current. The direction of output current flow and the sign of the output voltage depends on the magnetization orientation of the ferromagnet.

Reference is now made to the drawings, which are not necessarily drawn to scale, wherein similar or same numbers may be used to designate same or similar parts in different figures. The use of similar or same numbers in different figures does not mean all figures including similar or same numbers constitute a single or same embodiment. Like numerals having different letter suffixes may represent different instances of similar components. The drawings illustrate generally, by way of example, but not by way of limitation, various embodiments discussed in the present document.

In the following description, specific details are set forth, but embodiments of the technologies described herein may be practiced without these specific details. Well-known circuits, structures, and techniques have not been shown in detail to avoid obscuring an understanding of this description. Phrases such as “an embodiment,” “various embodiments,” “some embodiments,” and the like may include features, structures, or characteristics, but not every embodiment necessarily includes the particular features, structures, or characteristics.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or any other manner. “Connected” may indicate elements are in direct physical or electrical contact with each other and “coupled” may indicate elements co-operate or interact with each other, but they may or may not be in direct physical or electrical contact. Furthermore, the terms “comprising,” “including,” “having,” and the like, as used with respect to embodiments of the present disclosure, are synonymous.

Terms modified by the word “substantially” include arrangements, orientations, spacings, or positions that vary slightly from the meaning of the unmodified term. For example, reference to an axis of a valleytronic device that is substantially orthogonal to an axis of a ferromagnet includes valleytronic device and ferromagnet axes that are within five degrees of being orthogonal to each other. Values modified by the word “about” include values with +/−10% of the listed values and values listed as being within a range include values within a range from 10% less than the listed lower end of the range and 10% greater than the listed higher end of the range.

In the following description, for purposes of explanation, numerous specific details are set forth in order to provide a thorough understanding thereof. It may be evident, however, that the novel embodiments can be practiced without these specific details. In other instances, well known structures and devices are shown in block diagram form in order to facilitate a description thereof. The intention is to cover all modifications, equivalents, and alternatives within the scope of the claims

As used herein, the phrase “located on” in the context of a first layer or component located on a second layer or component refers to the first layer or component being directly physically attached to the second part or component (no layers or components between the first and second layers or components) or physically attached to the second layer or component with one or more intervening layers or components. As used herein, the term “adjacent” refers to layers or components that are in physical contact with each other. That is, there is no layer or component between the stated adjacent layers or components. For example, a layer X that is described as being adjacent or positioned adjacent to a layer Y refers to a layer that is in physical contact with layer Y.

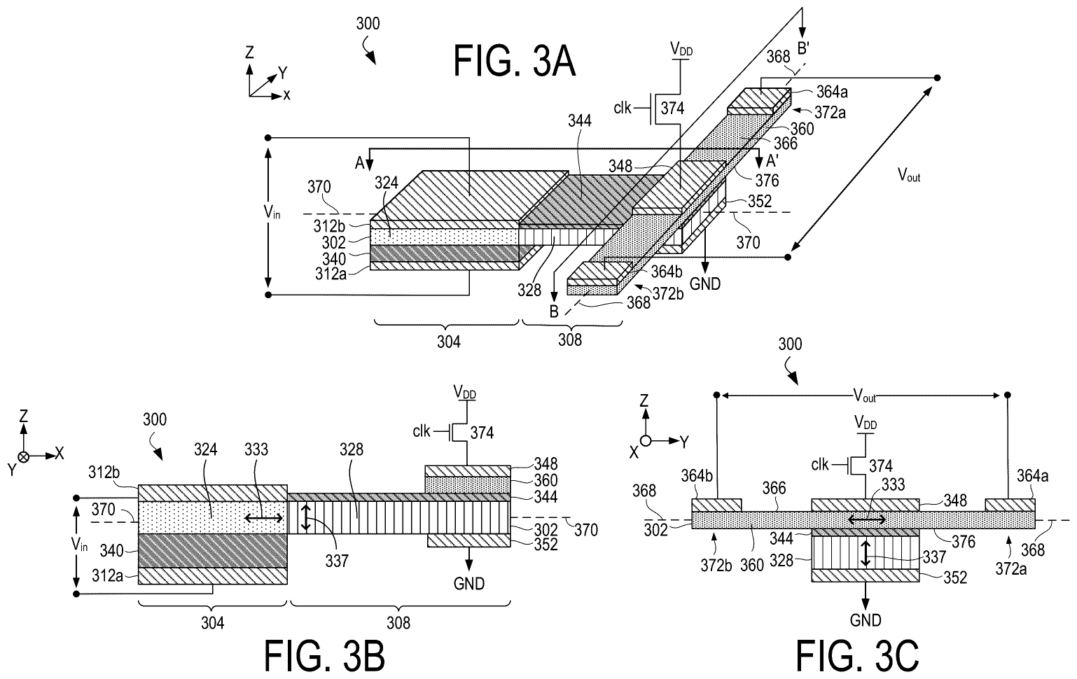

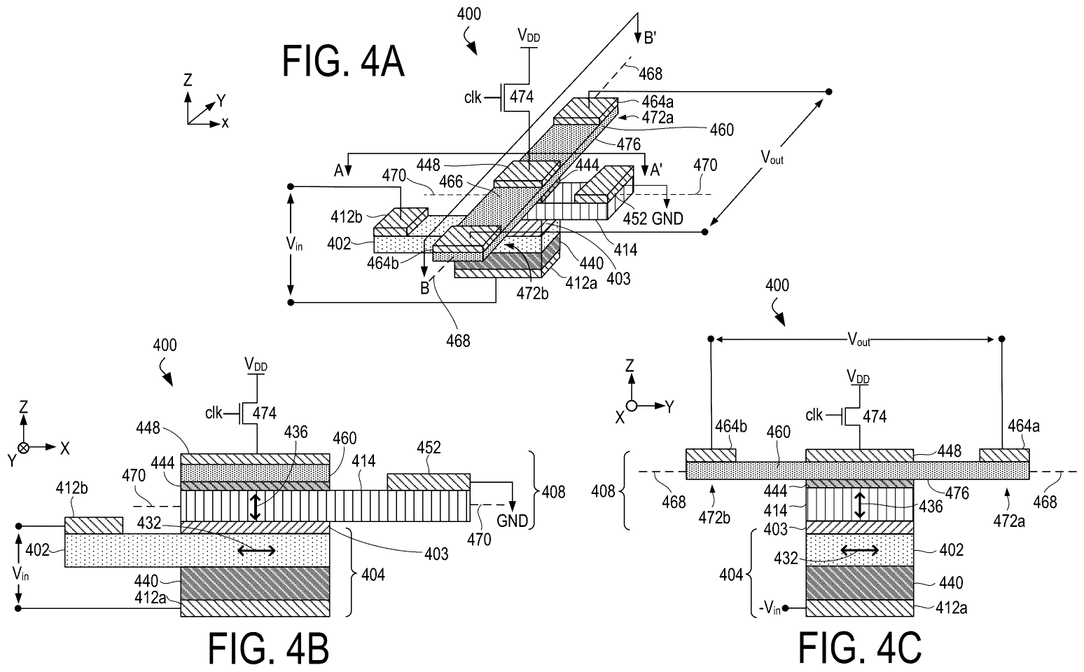

As used herein, reference to a first layer being “positioned between” second and third layers includes first layers that are completely or partially between the second and third layers. For example, with reference to FIGS. 3A-3C, the oxide layer 344 is positioned between the valleytronic monolayer 360 and the second portion 328 of the ferromagnet 302 even though a portion of the oxide layer 344 extends past an edge of the valleytronic monolayer 360. Further, with reference to FIGS. 4A-4C, the IMA ferromagnet 402 is positioned between the magnetoelectric layer 440 and the conductive trace 412b even though a portion of the IMA ferromagnet 402 extends past an edge of the conductive trace 412b.

As used herein, the term “integrated circuit component” refers to a packaged or unpacked integrated circuit product. A packaged integrated circuit component comprises one or more integrated circuit dies mounted on a package substrate with the integrated circuit dies and package substrate encapsulated in a casing material, such as a metal, plastic, glass, or ceramic. In one example, a packaged integrated circuit component contains one or more processor units mounted on a substrate with an exterior surface of the substrate comprising a solder ball grid array (BGA). In one example of an unpackaged integrated circuit component, a single monolithic integrated circuit die comprises solder bumps attached to contacts on the die. The solder bumps allow the die to be directly attached to a printed circuit board. An integrated circuit component can comprise one or more of any computing system component described or referenced herein or any other computing system component, such as a processor unit (e.g., system-on-a-chip (SoC), processor core, graphics processor unit (GPU), accelerator, chipset processor), I/O controller, memory, or network interface controller.

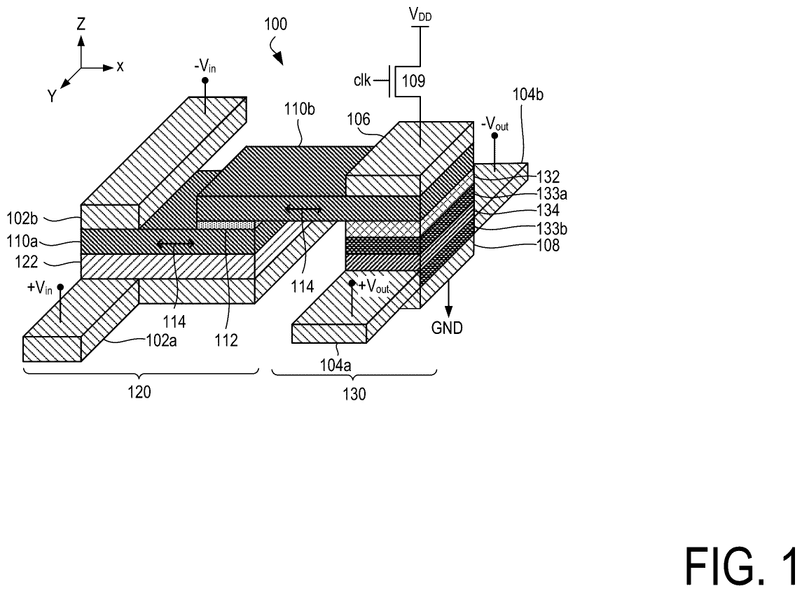

FIG. 1 illustrates an example differential magnetoelectric spin-orbit (MESO) logic device. MESO device 100 includes a ferromagnet 110, a magnetoelectric charge-to-spin conversion input module 120 (magnetoelectric module, magnetoelectric capacitor input module, input module, charge-to-spin conversion input module), and a spin-to-charge conversion output module 130 (spin-orbit conversion module, output module, read out module). MESO device 100 also includes conductive traces, portions of which serve as electrodes, to provide differential voltage inputs (+/−Vᵢₙ), a power supply (VDD), and ground (GND), and carry differential voltage outputs (+/−Vₒᵤₜ). Conductive traces 102a-b provide differential input voltages (+/−Vᵢₙ), conductive traces 104a-b carry differential output voltage signals (+/−Vₒᵤₜ), conductive trace 106 provides power (VDD), and conductive trace 108 provides ground (GND) to the device 100.

The magnetoelectric module 120 performs charge-to-spin conversion to convert an electric charge current into spin (e.g., by inducing a particular magnetization orientation in the ferromagnet 110), and the spin-to-charge conversion module 130 performs spin-to-charge conversion to convert spin (e.g., the magnetization orientation induced on the ferromagnet 110) back into an electric charge current, as described further below.

The ferromagnet 110 is formed by ferromagnets 110a-b coupled via an inter-magnet insulating layer 112, which collectively function as a single ferromagnet. That is, when the magnetization orientation of one of the ferromagnets 110a-b changes, the magnetization orientation of the other ferromagnet changes.

The magnetoelectric module 120 comprises a structure configured to convert an electric charge current into spin (e.g., magnetization). The magnetoelectric module 120 is formed by the positive input voltage (+Vᵢₙ) conductive trace 102a, which is positioned adjacent to a magnetoelectric layer 122, which is in turn positioned adjacent to ferromagnet 110a, which is in turn positioned adjacent to the negative input voltage (−Vᵢₙ) interconnect 102b. In this manner, the magnetoelectric module 120 is configured as a capacitor, with ferromagnet 110a and input voltage interconnect 102a serving as capacitor plates on either side of the magnetoelectric layer 122. The magnetoelectric material 122 has both ferroelectric properties (e.g., can be electrically polarized with or without an applied electric field) and magnetic properties (e.g., may exhibit surface spin polarization which can be switched under the application of an external electric field).

When voltage is applied via the differential voltage inputs (+/−Vᵢₙ), an electric field in the +/−Z direction is established in magnetoelectric layer 122 depending on the polarity of the input current, which results in ferroelectric polarization in the magnetoelectric layer 122 and forms. For example, when a positive input differential voltage (+Vᵢₙ) is applied, an electric field forms in the +Z direction in the magnetoelectric layer 122, with a positive charge accumulating in the region of the positive voltage (+Vᵢₙ) conductive trace 102a adjacent to the magnetoelectric layer 122 and a negative charge accumulating in the region of the ferromagnet 110a adjacent to the magnetoelectric layer 122. When a negative input differential voltage (Vᵢₙ) is applied, an electric field forms in the −Z direction in the magnetoelectric layer 122, with a negative charge accumulating in the region of the positive voltage (+Vᵢₙ) conductive trace 102a adjacent to the magnetoelectric layer 122 and a positive charge accumulating in the region of the ferromagnet 110a adjacent to the magnetoelectric layer 122.

As these charges accumulate, the spin of electrons in the magnetoelectric layer 122 at the interface with ferromagnet 110a becomes aligned to form surface spin polarization, forming a magnetic field. The orientation of magnetization (spin) of the electrons in the surface spin polarization is defined by the orientation of ferroelectric polarization within the magnetoelectric layer 122. As the magnetic field corresponding to the surface spin polarization is formed, it becomes exchange coupled with ferromagnet 110a, causing the magnetization in ferromagnet 110a to align in an in-plane orientation with the magnetic field of the surface spin polarization of the magnetoelectric layer 122, which in turn causes the same magnetization orientation to occur in ferromagnet 110b. The in-plane magnetization orientation of the ferromagnets 110a-b are indicated by arrows 114. In this manner, the magnetization orientation of the ferromagnet 110 can be switched based on an applied input current. Setting the magnetization orientation of the ferromagnet 110 affects the output of the spin-to-charge conversion output module 130, as described below.

The spin-orbit conversion module 130 is configured to convert electron spin (e.g., the magnetization) into an electric charge current. The spin-orbit conversion module 130 comprises the power supply (VDD) conductive trace 106, which is positioned adjacent to ferromagnet 110b, which is in turn positioned adjacent to a tunneling barrier 132. The tunneling barrier 132 is positioned adjacent to a first spin injection layer 133a, which is in turn positioned adjacent to spin-orbit coupling layer 134. The spin-orbit coupling layer 134 is positioned adjacent to a second spin injection layer 133b, which is positioned adjacent to the conductive traces 104a and 104b.

The supply of power to the ferromagnet 110b is controlled via a transistor 109 that has its gate terminal connected to a clock signal or other control signal. For example, when a voltage (e.g., 100 mV) is applied via the power supply (VDD) conductive trace 106, a supply charge current (I_{supply}) flows through ferromagnet 110b. The magnetization of the ferromagnet 110b produces a spin-polarized current in which a substantial majority (e.g., greater than 80%) of electrons associated with the supply charge current (I_{supply}) exhibits spin (e.g., magnetization) having an orientation corresponding to the magnetization of ferromagnet 110b. The strength of the spin-polarized current (e.g., the proportion of electrons that align with ferromagnet 110b) is proportional to the strength of the magnetization.

After the supply current passes through ferromagnet 110b and becomes spin-polarized, it enters the tunneling barrier 132, which serves as a tunneling barrier to the spin-orbit coupling layer 134. Because the ferromagnet 110b can have low resistance and the spin-orbit coupling layer 134 can have high resistance, if those components are adjacent to each other, spin current can flow from the spin-orbit coupling layer 134 back into the ferromagnet 110b. The placement of the tunneling barrier 132 between the ferromagnet 110b and the spin-orbit coupling layer 134 can prevent or reduce the amount of spin current flowing from the spin-orbit coupling layer 134 back into the ferromagnet 110b. In this manner, the spin current flows from ferromagnet 110b through the tunneling barrier 132 and into the spin-orbit coupling layer 134, with a small amount or no spin current flow in the opposite direction. The spin injection layer 133a can further improve the spin polarization of electrons injected into the spin-orbit coupling layer 134.

The spin-orbit coupling layer 134 has a strong spin-orbit effect, which is referred to as spin-orbit coupling. As a result, when the spin current flows through the spin-orbit coupling layer 134, due to the inverse spin Hall effect, the spin current converts into an output charge current, which produces an output voltage on the differential output conductive traces (+/−Vₒᵤₜ) 104a-b. A spin injection layer 133b is coupled to the spin-orbit coupling layer 134 and the output conductive traces 104a-b.

The transformation of a spin-polarized current into a charge current when the spin-polarized current flows through a material with high spin-orbit coupling is referred to as the inverse spin Hall effect (ISHE). By contrast, the standard spin Hall effect (SHE) is a phenomenon where a charge current transforms into a spin current when the charge current flows through a material with high spin-orbit interaction. The directions of the spins are opposite at opposing lateral boundaries of the material, and the spin polarization is proportional to the current and changes sign when the direction of the current is reversed. Thus, the inverse spin Hall effect is simply the reverse of the spin Hall effect.

In the illustrated example, the spin-orbit conversion module 130 is configured so that the direction of deflection of the electrons due to the inverse spin Hall effect is either in the positive or negative direction along the Y-axis of the differential voltage output conductive traces (+/−Vₒᵤₜ) 104a-b, which serve as the output of the MESO device 100. The deflection of electrons produced by the inverse spin Hall effect is along an axis (e.g., the Y-axis) that is substantially perpendicular to both the supply charge current (I_{supply}) (e.g., the Z-axis) and the spin-polarized current corresponding to the orientation of magnetization (e.g., the X-axis). Thus, the differential voltage outputs (+/−Vₒᵤₜ) 104a-b are positioned substantially perpendicular to ferromagnet 110b (and associated magnetization orientation) and substantially perpendicular to the direction of the supply charge current (I_{supply}). The spin-orbit coupling layer 134 deflects a majority of electrons toward the +Vₒᵤₜ conductive trace 104a or the −Vₒᵤₜ conductive trace 104b, thereby resulting in an output current that is proportional to the supply charge current (I_{supply}) and has a sign that is dependent on the magnetization orientation of the ferromagnet 110b. In this manner, an output voltage is produced on the differential voltage output conductive traces (+/−Vₒᵤₜ) 104a-b. A residual current may also pass through the spin-orbit coupling layer 134 to ground conductive trace 108.

In the illustrated example, the input voltage differential (+/−Vᵢₙ) and the supply charge current (I_{supply}) may be provided during separate operations implemented at different times. Applying an input voltage differential that sets or adjusts the orientation of magnetization of the ferromagnet 110 may be compared to a write operation. Further, providing a supply charge current (I_{supply}) that results in an output voltage differential (+/−Vₒᵤₜ), the sign of which reflects the magnetization orientation of the ferromagnet 110, being established during a write operation, may be compared to a read operation.

While MESO devices have low switching energy, their potential use as logic gates may be limited with the use of some currently available materials in the output module as the spin-to-charge conversion mechanism of these materials may be too weak to generate sufficient output current to change the logic state of another MESO device. That is, for MESO devices to be viable as logic gates, the magnitude of the output voltage of a MESO device needs to exceed the switching voltage (e.g., V_{coercive}) of the magnetoelectric capacitor of a succeeding MESO device.

Turning to valleytronic devices, the second device type referenced above as being examined as an alternative to CMOS electronic devices, valleytronic devices utilize valley-dependent material characteristics to store and/or carry information. Valleytronic devices can comprise 2D layers of a ferroelectric material that exhibit band spin-splitting. Such layers may be referred to herein as “2D valleytronic layers”.

Disclosed herein are valleytronic MESO devices, MESO devices that utilize a 2D valleytronic layer in its spin-to-charge conversion output module. The charge-to-spin conversion input module and the spin-to-charge conversion output module share a ferromagnet. The input module comprises a ferromagnet having in-plane magnetic anisotropy (IMA) and the output module comprises a ferromagnet having perpendicular magnetic anisotropy (PMA). The PMA ferromagnet is used to inject polarized spin current into the 2D valleytronic layer. The 2D valleytronic layer converts the polarized spin current into an output charge current via the inverse spin hall effect.

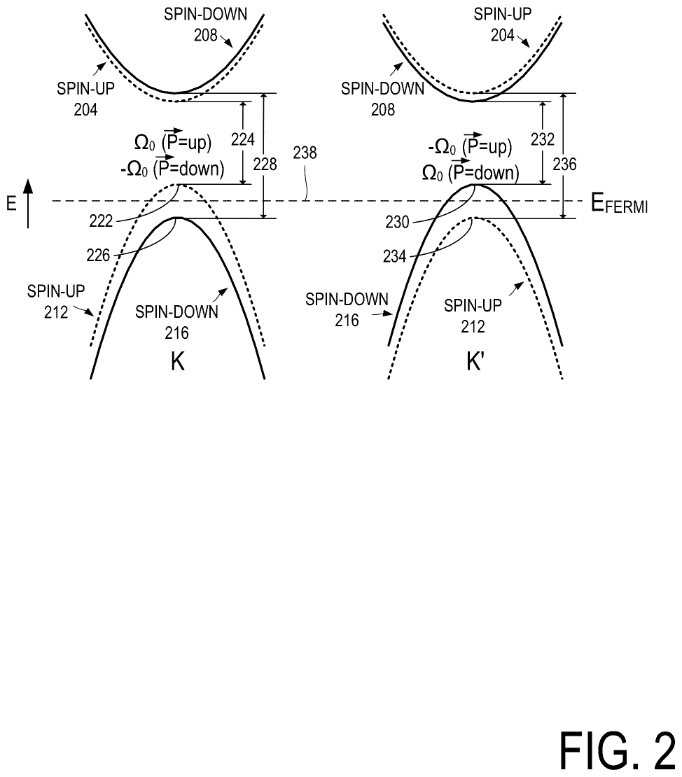

FIG. 2 illustrates energy band extrema for an example 2D valleytronic layer. FIG. 2 illustrates energy band spin-splitting and the Berry curvature of the K and K′ valleys of the layer under upward- and downward-pointing electric polarization. The energy bands for spin-up electrons (spin-up bands) are illustrated as dashed lines and the energy bands for spin-down electrons (spin-down bands) are illustrated as solid lines. As can be seen, the difference in the energy values of the conduction bands (spin-up bands 204 and spin-down bands 208) is less than the difference in the energy values of the valence bands (spin-up bands 212 and spin-down bands 216). The energy bandgap is smaller for different spin polarizations across the K and K′ valleys. At the K valley conduction band maximum, the bandgap 224 for spin-up electrons is smaller than the bandgap 228 for spin-down electrons, and at the K′ valley conduction band maximum, the bandgap 232 for spin-down electrons is smaller than the bandgap 236 for spin-up electrons.

Setting the Fermi level 238 between the K valley valence band maxima 222 and 226 and between the K′ valence band maxima 230 and 234, as shown in FIG. 2, allows for valley-selective carrier injection. That is, there will be a valley dependency on the spin polarization of electrons injected from the valence band to the conduction band. A majority of electrons injected into the K valley conduction band from the K valley valence band will be spin-up electrons and the majority of electrons injected into the K′ conduction band from the K′ valence band will be spin-down electrons.

FIG. 2 also illustrates the Berry curvature (Ω₀) valley dependence and the dependence of the Berry curvature on the electrical polarization of a 2D valleytronic layer (or valleytronic monolayer). When the 2D valleytronic layer possesses an upward polarization, the Berry curvatures of the K and K′ valleys are positive and negative, respectively. When the polarization of the layer is reversed and possesses a downward polarization, the signs of the Berry curvatures of the K and K′ valleys flip and are negative and positive, respectively. Charge carriers in a 2D valleytronic layer have an anomalous velocity that is proportional to the cross product of the Berry curvature and an applied electric field (E×Ω₀).

The valleytronic MESO devices disclosed herein utilize band spin-splitting to read out the logic state of the device, which is stored as the magnetization orientation of the IMA and PMA ferromagnets. Chiral coupling between the IMA and PMA ferromagnets through Dzyaloshinskii-Moriya interaction (DMI) causes the perpendicular magnetization orientation of the PMA ferromagnet to switch with the magnetization orientation of the IMA ferromagnet. If the spin current injected from the PMA ferromagnet into the 2D valleytronic layer is spin-up polarized, the 2D valleytronic layer will predominantly comprise spin-up electrons in the valley where the valence sub-band for spin up electrons is closest to the Fermi energy level (e.g., the K valley in FIG. 2) and have a positive Berry curvature. Conversely, if the injected spin current is spin-down polarized, the valleytronic layer will predominantly comprise spin-down electrons in the valley where the valence sub-band for spin down electrons is closest to the Fermi level (e.g., the K′ valley in FIG. 2) and have a negative Berry curvature.

As illustrated in FIGS. 3A and 4A, the valleytronic MESO devices disclosed herein have a “cross” geometry in which the 2D valleytronic layer is substantially orthogonal to the PMA ferromagnet. The spin-polarized charge current injected into the 2D valleytronic layer is converted into a differential voltage output across the 2D valleytronic layer via the inverse spin-valley Hall effect, whereby charge carriers acquire an anomalous velocity proportional to the Berry curvature. The anomalous velocity is along the direction of an axis that extends the length of the 2D valleytronic layer. Due to spin-up and spin-down electrons having Berry curvatures of opposite signs, as illustrated in FIG. 2, the polarity of the output voltage depends on the spin polarization of the spin current injected into the 2D valleytronic layer from the PMA ferromagnet.

The valleytronic MESO devices described herein have at least the following advantages. First, the spin-to-charge conversion output module has a simpler stack design relative to the MESO device illustrated in FIG. 1. Second, chiral coupling is more robust and versatile compared to coupling through dipolar exchange coupling fields. Third, the charge-to-spin conversion input modules comprise a ferromagnet having in-plane magnetic anisotropy, which is presently more technologically mature compared to magnetoelectric capacitor input modules comprising a ferromagnetic with perpendicular magnetic anisotropy. Fourth, the MESO device design illustrated in FIG. 1 is limited to ferromagnetic layers that possess in-plane anisotropy. Fifth, the PMA ferromagnet in the spin-to-charge conversion output module allows for the injection of out-of-plane spin current into a valleytronic monolayer that has a strong valley-coupled spin Hall effect, which allows for a larger output current/voltage than possible in MESO devices having a spin-to-charge output module of the type illustrated in FIG. 1 and using existing industrially relevant spin-orbit coupling materials.

FIGS. 3A-3C illustrate a first example valleytronic MESO device. FIG. 3A illustrates a perspective view of valleytronic MESO device 300 and FIGS. 3B and 3C illustrate cross-sectional views of the device 300 taken along the lines A-A′ and B-B′ of FIG. 3A, respectively. Device 300 includes a ferromagnetic layer (ferromagnet) 302, magnetoelectric charge-to-spin conversion input module 304 and a spin-to-charge conversion output module 308. Valleytronic MESO device 300 also comprises conductive traces 312a-b that provide differential input voltages (+/−Vᵢₙ), conductive traces 364a-b that carry differential output voltage signals (+/−Vₒᵤₜ), conductive trace 348 that provides power (VDD), and conductive trace 352 that provides ground (GND) to the device 300.

The magnetoelectric module 304 converts an electric charge current into spin by inducing a particular magnetization orientation in the ferromagnet 302, which can be considered to store the logic state of the valleytronic MESO device. The spin-orbit conversion module 308 acts to read out the MESO device logic state by converting the magnetic orientation of the ferromagnet to an electric charge current, as described further below.

The magnetoelectric module 304 comprises a magnetoelectric layer 340 positioned adjacent to a first portion 324 of the ferromagnet 302, with the magnetoelectric layer 340 and the first portion 324 of the ferromagnet 302 positioned between the input voltage conductive traces 312a and 312b. The conductive trace 312a is positioned adjacent to the magnetoelectric layer 340 and the conductive trace 312b is positioned adjacent to the first portion 324 of the ferromagnet 302. The magnetoelectric layer 340 is positioned between the first portion 324 of the ferromagnet 302 and the conductive trace 312a. The magnetoelectric layer 340 comprises a material that has both ferroelectric properties and magnetic properties.

The ferromagnet 302 extends along an axis 370 from the first portion 324 to a second portion 328 of the ferromagnet. The first portion 324 has in-plane magnetic anisotropy and the second portion 328 has perpendicular magnetic anisotropy, as indicated by arrows 333 and 337, respectively. The first and second portions 324 and 328 of the ferromagnet 302 may thus be referred to herein as IMA and PMA ferromagnets 324 and 328. The IMA and PMA ferromagnets 324 and 328 are chirally-coupled due to the presence of Dzyaloshinskii-Moriya interaction, which acts to preserve the chirality of the IMA ferromagnet-PMA ferromagnet system. This coupling ensures that when the in-plane magnetization orientation of the IMA ferromagnet 324 switches, the perpendicular magnetization orientation of the PMA ferromagnet 328 switches as well.

The operation of the input module 304 is similar to that of the input module 120 of the device 100 illustrated in FIG. 1. When voltage is applied via the differential voltage inputs, ferroelectric polarization occurs in the magnetoelectric layer 340. As an electric field is established across the magnetoelectric module 304, the spin of electrons in the magnetoelectric layer 340 at the interface with ferromagnet 302 becomes aligned to form surface spin polarization, forming a magnetic field. The orientation of magnetization (spin) of the electrons in the surface spin polarization is defined by the orientation of ferroelectric polarization within the magnetoelectric layer 340. As the magnetic field corresponding to the surface spin polarization is formed, it becomes exchange coupled with IMA ferromagnet 324, causing the in-plane magnetization orientation of the IMA ferromagnet 324 to align with the magnetic field of the surface spin polarization of the magnetoelectric layer 340. In this manner, the magnetization orientation of the IMA ferromagnet 324 can be switched based on the input voltage. As described above, chiral coupling between the IMA and PMA ferromagnets 324 and 328 causes the perpendicular magnetic orientation of the PMA ferromagnet 328 to switch with that of the in-plane magnetization orientation of the IMA ferromagnet 324.

The perpendicular magnetic anisotropy of the PMA ferromagnet 328 can be established through the presence of an interfacial oxide layer (oxide layer) 344 positioned adjacent to the ferromagnet 302. In some embodiments, formation of the IMA and PMA ferromagnets 324 and 328 is performed by first forming a ferromagnet 302 that has an in-plane magnetic anisotropy and then selectively forming an interfacial oxide layer positioned adjacent to the ferromagnet 302 where it is desired for the ferromagnet 302 to possess perpendicular magnetic anisotropy.

The spin-to-charge conversion output module 308 comprises a conductive trace 348 that provides power to the device, a conductive trace 352 that provides a connection to ground, a 2D valleytronic monolayer 360, the second portion 328 of the ferromagnet 302, the oxide layer 344, and a pair of conductive traces 364a-b to provide the differential output of the device 300. The 2D valleytronic monolayer 360 extends along an axis 368 that is substantially orthogonal to the axis 370 of the ferromagnet 302. The conductive traces 364a-b providing the differential output signals are positioned adjacent to a surface 366 of the 2D valleytronic monolayer 360 at opposite end portions 372a-b of the monolayer.

The PMA ferromagnet 328, the interfacial oxide layer 344, and the 2D valleytronic monolayer 360 are positioned between the conductive traces 348 and 352. The PMA ferromagnet 328 is positioned adjacent to the conductive trace 352 providing ground, the valleytronic monolayer 360 is positioned adjacent to the interfacial oxide layer 344 and the interfacial oxide layer 344 is positioned between the 2D valleytronic monolayer 360 and the PMA ferromagnet 328. The interfacial oxide layer 344 is positioned adjacent to a surface 376 of the 2D valleytronic monolayer 360. The supply of power to the device 300 to read out the logic state of the device 300 is controlled via a transistor 374 that has its gate terminal connected to a clock signal or other control signal. In some embodiments, the sequence of layers comprising the output module 308 can be flipped vertically from the arrangement shown in FIG. 3A. That is, in some embodiments, the conductive trace providing ground can be the topmost layer in the output module stack and the conductive trace providing power can be the bottommost layer in the output module stack.

When voltage is applied via the power supply (VDD) conductive trace 348, a spin-polarized current is injected from the PMA ferromagnet 328 into the 2D valleytronic monolayer 360. A substantial majority (e.g., greater than 80%) of electrons associated with the spin-polarized current will have a spin that corresponds to the magnetization orientation of the PMA ferromagnet 328. The electrons in the injected spin current flowing in the 2D valleytronic material have a Berry curvature with a sign that is dependent on its spin polarization. As the electrons have an anomalous velocity that is proportional to the cross product of the Berry curvature and the electric applied across the 2D valleytronic monolayer, the charge carriers of the injected spin current will be deflected along the length of the 2D valleytronic monolayer 360 (e.g., in the positive or negative direction along the Y-axis, along the axis 368) and accumulate at one of the ends of 2D valleytronic monolayer 360 depending on the spin polarity of the injected spin current. This will result in the creation of a differential output voltage across the conductive traces 364a-b, the sign of which will depend on the spin polarity of the injected spin current, and hence, the stored logic state of the valleytronic MESO device 300.

FIGS. 4A-4C illustrate a second example valleytronic MESO device. The device 400 varies from the device 300 in that the IMA and PMA ferromagnets are not positioned adjacent to each other and are stacked vertically with respect to each other. FIG. 4A illustrates a perspective view of valleytronic MESO device 400 and FIGS. 4B and 4C illustrate cross-sectional views of the device 400 taken along the lines A-A′ and B-B′ of FIG. 4A, respectively. Device 400 comprises an IMA ferromagnet 402, a charge-to-spin conversion input module 404, a PMA ferromagnet 414, and a spin-to-charge conversion output module 408. The magnetic anisotropy of the IMA and PMA ferromagnets is indicated by arrows 432 and 436, respectively. Device 400 also includes conductive traces 412a-b to provide differential input voltages, conductive trace 448 to provide power, conductive trace 452 to provide ground, and conductive traces 464a-b to carry differential output voltages.

The magnetoelectric module 404 comprises the IMA ferromagnet 402, a magnetoelectric layer 440 positioned adjacent to the IMA ferromagnet 402, and input voltage conductive traces 412a-b. Conductive trace 412a is positioned adjacent to the magnetoelectric layer 440 and the conductive trace 412b is positioned adjacent to the IMA ferromagnet 402.

The spin-to-charge conversion output module 408 comprises the conductive traces providing power (448) and ground (452) along with those carrying the differential output signals (464a-b), a 2D valleytronic monolayer 460, the PMA ferromagnet 414, and an interfacial oxide layer 444. The PMA ferromagnet 414 extends lengthwise along an axis 470 and the 2D valleytronic monolayer 460 extends along an axis 468 that is substantially orthogonal to the axis 470. The conductive traces 464a-b providing the differential output signal are positioned adjacent to a surface 466 of the 2D valleytronic monolayer 460 at opposite end portions 472a-b of the monolayer.

The PMA ferromagnet 414, the interfacial oxide layer 444, and the 2D valleytronic monolayer 460 are positioned between the conductive traces 448 and 452. The 2D valleytronic monolayer 460 is positioned adjacent to the interfacial oxide layer 444 and the interfacial oxide layer 444 is positioned between the 2D valleytronic monolayer 460 and the PMA ferromagnet 414. The interfacial oxide layer 444 is positioned adjacent to a surface 476 of the 2D valleytronic monolayer 460 that is opposite the surface 466. The conductive trace 452 providing a connection to ground is positioned adjacent to the PMA ferromagnet 414.

The IMA ferromagnet 402 is chirally-coupled to the PMA ferromagnet 414. A coupling layer 403 is positioned between the IMA ferromagnet 402 and the PMA ferromagnet 414 to establish the chiral coupling between the IMA and PMA ferromagnets 402 and 414. The presence of DMI between the chirally-coupled ferromagnets 402 and 414 ensures that the perpendicular magnetization orientation of the PMA ferromagnet 414 switches with the in-plane magnetization orientation of the IMA ferromagnet 402. As in the valleytronic MESO device 300, the logic state of the valleytronic MESO device 400 stored in the magnetization orientations of the IMA and PMA ferromagnets.

The operation of the magnetoelectric input module 404 is similar to that of the input modules 120 and 304 of the devices 100 and 300, respectively. That is, application of a differential input voltage sets the magnetization orientation of the IMA ferromagnet 402, the magnetization orientation of the PMA ferromagnet 414 switches with that of the IMA ferromagnet 402 through chiral coupling, and the logic state of the device 400 is read out by the spin-to-charge conversion output module, which provides an output voltage having a polarity depending on the magnetization orientation of the PMA ferromagnet 414.

Similar to how perpendicular magnetic anisotropy can be established in the second ferromagnet 328 of device 300 through the presence of an interfacial oxide layer positioned adjacent to an IMA ferromagnet, the perpendicular magnetic anisotropy of the ferromagnet 414 can be induced through the presence of an interfacial oxide layer 444 positioned adjacent to the ferromagnet 414. In some embodiments, the ferromagnet 414 possesses perpendicular magnetic anisotropy without the presence of an adjacent interfacial oxide layer. That is, there is no interfacial oxide is present between the PMA ferromagnet and the 2D valleytronic layer. Various PMA ferromagnet/interfacial oxide layer stacks and ferromagnetic layers that possess PMA without the presence of an adjacent interfacial oxide layer are discussed below.

The supply of power to the device 400 to read out the logic state of the device 400 is controlled via a transistor 474 that has its gate terminal connected to a clock signal or other control signal. In some embodiments, the conductive trace 452 that provides the ground connection can be located on the opposite side of the PMA ferromagnet 414 from what is shown in FIGS. 4A and 4C. That is, in other embodiments, the conductive trace 452 can be located on the same side of the PMA ferromagnet 414 as the coupling layer 403.

Reading the stored logic state of the device 400 is performed in a similar manner as for the device 300. When voltage is applied via the power supply (VDD) conductive trace 448, a spin-polarized current is injected from the PMA ferromagnet 414 into the 2D valleytronic monolayer 460. A substantial majority of electrons associated with the spin-polarized current will exhibit spin having an orientation corresponding to the magnetization orientation of the PMA ferromagnet 414. The charge carriers in the injected spin-polarized current flowing in the 2D valleytronic monolayer 460 have a Berry curvature with a sign that is dependent on their spin polarization. As the charge currents have an anomalous velocity that is proportional to the cross product of the Berry curvature and the electric applied across the valleytronic material by power supply voltage, the charge carriers of the injected spin-polarized current will be deflected along the length of the 2D valleytronic monolayer 460 (e.g., along the axis 468) and accumulate at one of the ends of 2D valleytronic monolayer 460 depending on the spin polarity of the injected spin current. This will result in the creation of a differential output voltage at the conductive traces 464a-b, the sign of which depends on the spin polarity of the injected spin current, and hence, the stored logic state of the valleytronic MESO device 400.

Providing a differential input voltage to a valleytronic MESO device may be compared to a write operation in that it sets the magnetic polarizations of the IMA and PMA ferromagnets. Further, providing power to the output module of a valleytronic MESO device may be compared to a read operation in that doing so produces an output voltage differential that depends on the magnetization orientation of the IMA and PMA ferromagnets. As the magnetic orientation of the IMA and PMA ferromagnets are retained after an applied input voltage is removed, the valleytronic MESO devices disclosed herein can be used as logic devices (e.g., a logic switch/gate) with non-volatile logic states.

Although FIGS. 3A-3C and 4A-4C show layers with edges aligned with edges of another layer, in some embodiments, edges shown as being aligned in FIGS. 3A-3C and 4A-4C may not be aligned. For example, an edge of the ferromagnet 302 may extend past an edge of the interfacial oxide layer 344 or magnetoelectric layer 340. Similarly, an edge of the magnetoelectric layer 340 may extend past an edge of the ferromagnet 302. Further, an edge of conductive traces 364a, 364b, and/or 348 can extend past an edge of the 2D valleytronic monolayer 360 and/or an edge of the 2D valleytronic monolayer 360 can extend past an edge of conductive traces 364a, 364b, and/or 348.

The 2D valleytronic layer of any of the valleytronic MESO devices disclosed herein (e.g., 360, 460) comprises a suitable material possessing the properties of band-spin splitting and Berry curvature polarity valley dependency. In some embodiments, the 2D valleytronic layer is a transition metal dichalcogenide (TMD). TMDs have the chemical formula MX₂ where M is a transition metal and X is a chalcogenide, such as sulfur, selenium, or tellurium. The 2D valleytronic layer can be a TMD monolayer, which comprises a layer of M atoms between two layers of X atoms. In some embodiments, the 2D valleytronic layer is a TMD with titanium, molybdenum, tungsten, platinum, erbium, lanthanum, or rhodium as the transition metal and sulfur, selenium, or tellurium as the chalcogenide. That is, in some embodiments, the TMD monolayer can be molybdenum disulfide (MoS₂), molybdenum diselenide (MoSe₂), molybdenum ditelluride (MoTe₂), titanium disulfide (TiS₂), titanium diselenide (TiSe₂), titanium ditelluride (TiTe₂), tungsten disulfide (WS₂), tungsten diselenide (WSe₂), tungsten ditelluride (WTc₂), platinum disulfide (PtS₂), platinum diselenide (PtSe₂), platinum ditelluride (PtTe₂), erbium disulfide (ErS₂), erbium diselenide (ErSe₂), erbium ditelluride (ErTe₂), rhodium disulfide (RhS₂), rhodium diselenide (RhSe₂), rhodium ditelluride (RhTe₂), lanthanum disulfide (LaS₂), lanthanum diselenide (LaSe₂), or lanthanum ditelluride (LaTe₂).

In other embodiments, the 2D valleytronic monolayer is a ferroelectric monochalcogenide, a material having the chemical composition MX, where M can be tin (Sn) or germanium (Ge) and X can be sulfur (S), selenium (Se), and tellurium (Te). Thus, the 2D valleytronic layer can comprise tin sulfide (SnS), tin selenide (SnSe), tin telluride (SnTe), germanium sulfide (GeS), germanium selenide (GeSe), or germanium telluride (GeTe). In some embodiments, the 2D valleytronic layer comprises a compositional alloy having the chemical composition MX₁X₂ where M can be tin or germanium and X₁ and X₂ are two different X elements (e.g., two different elements of sulfur, selenium, and tellurium), such as SnS_{y}Se_{1-y}. In some embodiments, the 2D valleytronic layer comprises a compositional alloy having the chemical composition Ge_{y}Sn_{1-y}X, where X is sulfur, selenium, or tellurium, such as Ge_{y}Sn_{1-y}Te. In some embodiments, the 2D valleytronic layer is a monochalcogenide monolayer. In other embodiments, the channel layer comprises multiple layers of a monochalcogenide or a TMD but is thin enough to still possess the band-spin splitting and Berry curvature polarity valley dependency properties of a monochalcogenide or TMD monolayer. In some embodiments, the 2D valleytronic layer has a thickness in the range of 1-15 nanometers. In some embodiments, the 2D valleytronic layer comprises graphene proximitized by a TMD. That is, the 2D valleytronic layer comprises a monolayer of carbon atoms arranged in a hexagonal pattern positioned adjacent to a TMD monolayer.

The magnetoelectric layer of any of the valleytronic MESO devices disclosed herein can comprise any suitable magnetoelectric and/or multiferroic material (e.g., a multiferroic oxide), such as a material that includes, for example, bismuth (Bi), iron (Fe), oxygen (O), lanthanum (La), chromium (Cr), and/or boron (B), such as bismuth iron oxide (BiFeO₃ or BFO), doped bismuth iron oxide (e.g., BiFcO₃ doped with lanthanum, ((Bi₁₋ₓ Laₓ)FeO₃ or LBFO), chromium oxide (Cr₂O₃), and doped chromium oxide (e.g., Cr₂O₃ doped with boron). In some embodiments, the thickness of the magnetoelectric layer can be in the range of 1-100 nanometers (nm).

The IMA ferromagnet of any of the valleytronic MESO devices disclosed herein (e.g., 302, 402) can comprise any suitable conducting ferromagnetic material, such as cobalt, iron, nickel, or an alloy of conducting ferromagnetic material, such as CoFe, CoFeB, and NiFe, as well as ferromagnetic metallic oxides, such as Sr₂FeMoO₆ (SFMO), Sr₂CrRcO₆ (SCRO), La_{0.7}Sr_{0.3}MnO₃ (LSMO), or Fe₃O₄. The thickness of an IMA ferromagnet can be in the range of 1.5-50 nm. The thickness of an IMA ferromagnet can be limited by exchange coupling and exchange bias with the magnetoelectric layer, which scales inversely with IMA ferromagnet thickness.

The PMA ferromagnet of any of the valleytronic MESO devices disclosed herein can comprise a bilayer stack comprising a ferromagnetic layer positioned adjacent to an interfacial oxide layer (e.g., 328/344 stack, 414/444 stack). In such embodiments, the ferromagnetic layer can comprise a suitable conducting ferromagnetic material, such as cobalt, iron, or an alloy of conducting ferromagnetic material, such as CoFe or CoFeB and the oxide layer can comprise MgO, an aluminum oxide (e.g., AlO, Al₂O, Al₂O₃), or an oxide of the ferromagnetic layer material (e.g., an iron oxide (e.g., FeO, Fe₂O₃, Fe₃O₄), a cobalt oxide (e.g., CoO, Co₂O₃, Co₃O₄). In these ferromagnet/oxide bilayer stacks, the thickness of the ferromagnetic layer is in the range of 0.5-1.5 nanometers and the thickness of the oxide layer is in the range of 0.5-10 nanometers.

In embodiments where the PMA ferromagnet is not positioned adjacent to the IMA ferromagnet and is stacked vertically with the IMA ferromagnet (e.g., PMA ferromagnet 414), the PMA ferromagnet can comprise a superlattice comprising a stack of one or more sub-layers comprising cobalt alternating with one or more sub-layers comprising platinum. The thickness of the cobalt and platinum sub-layers in the superlattice can be in the range of 0.5-1.5 nanometers.

In embodiments where the PMA ferromagnet is not positioned adjacent to the IMA ferromagnet and is stacked vertically with the IMA ferromagnet, the PMA ferromagnet can be a 2D or multilayer ferromagnet comprising, for example, iron, phosphorous, and sulfur, such as FcPS₃; chromium, germanium, and tellurium, such as Cr₂Ge₂Te₆; chromium and iodine, such as CrI₃; nickel, phosphorous, and sulfur, such as NiPS₃; manganese, phosphorus, and sulfur, such as MnPS₃, or iron, germanium, and tellurium, such as Fe₃GeTe₂. In such embodiments where the PMA ferromagnet is a 2D ferromagnet, the thickness of the PMA ferromagnet can be less than 0.5 nanometers. In such embodiments where the PMA ferromagnet is a multilayer ferromagnetic, the thickness of the PMA ferromagnet can be greater than 50 nanometers.

The coupling layer in any of the valleytronic MESO devices described herein comprising IMA and PMA ferromagnets that are not positioned adjacent to each other and are stacked vertically (e.g. coupling layer 403) can comprise a material that includes iron (Fe), oxygen (O), cobalt (C), europium (Eu), nickel (Ni), titanium (Ti), yttrium (Y), magnesium (Mg), and/or aluminum (Al), such as Iron(II, III) oxide (Fe₃O₄), Iron(II) oxide (Fe₂O₃), cobalt ferrite (CoFe₂O₄), Europium(II) oxide (EuO), Cobalt(III) oxide (Co₂O₃), Co₂FeO₄, Ni₂FeO₄, (Ni,Co)₁₊₂ₓTi₍₁₋ₓ₎O₃, yttrium iron garnet (Y₃Fe₅O₁₂ or YIG), aluminum-doped magnesium ferrite, (MgAl_{0.5}Fe_{1.5}O₄ or MAFO), and aluminum-doped nickel ferrite (NiAlₓFe₂₋ₓO₄ or NiAFO). The thickness of the coupling layer can be in the range of 0.5-5 nanometers.

The conductive traces in any of the valleytronic MESO devices described herein (e.g., 312a-b, 348, 352, 364a-b, 412a-b, 448, 452, 464a-b) can be any suitable material, such as copper, aluminum, silver, gold, cobalt, tungsten, tantalum, nickel, or another conductive material. In some embodiments where the magnetoelectric layer is BiFeO₃, the conductive trace positioned adjacent to the magnetoelectric layer comprises a material comprising strontium (Sr), ruthenium (Ru), and oxygen, such as SrRuO₃ (SRO), which can provide for better growth of BiFcO₃ during valleytronic MESO device fabrication. In some embodiments, the thicknesses of the conductive traces can be in the range of 1-500 nanometers.

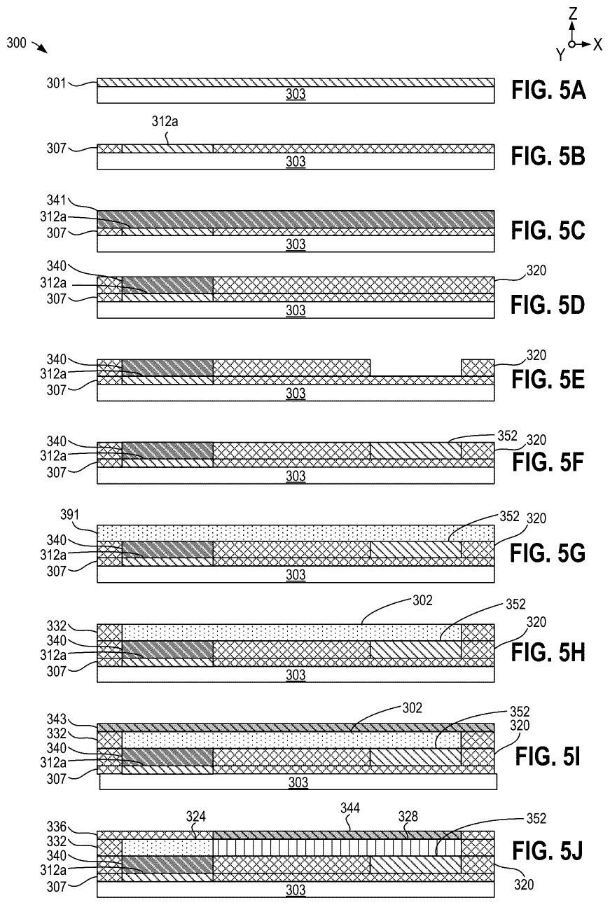

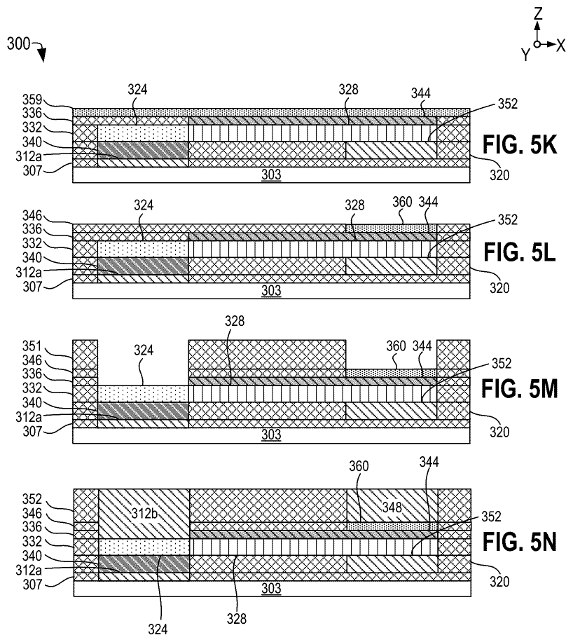

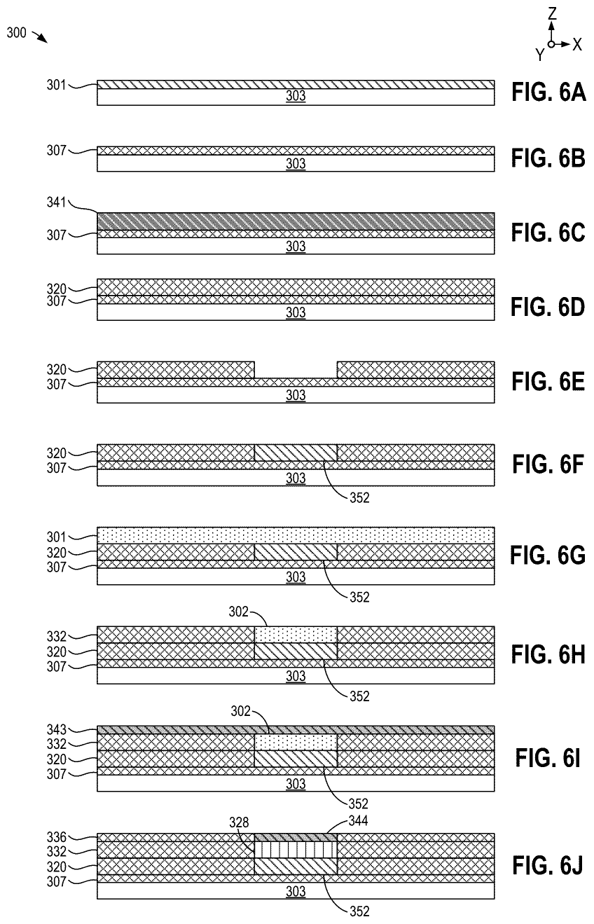

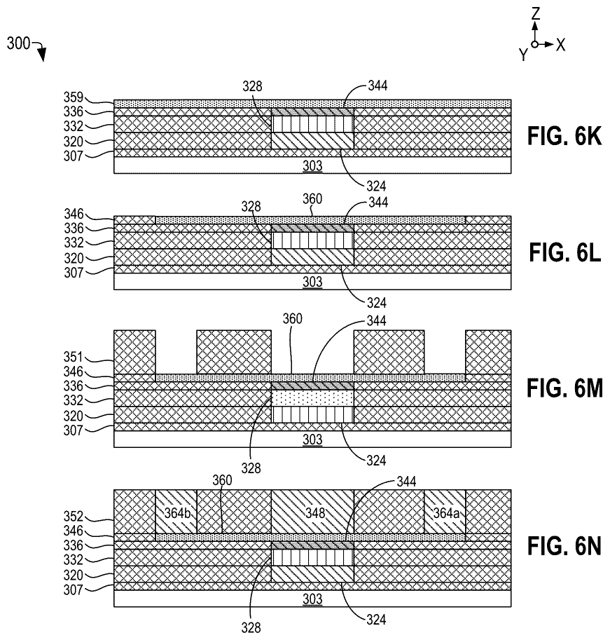

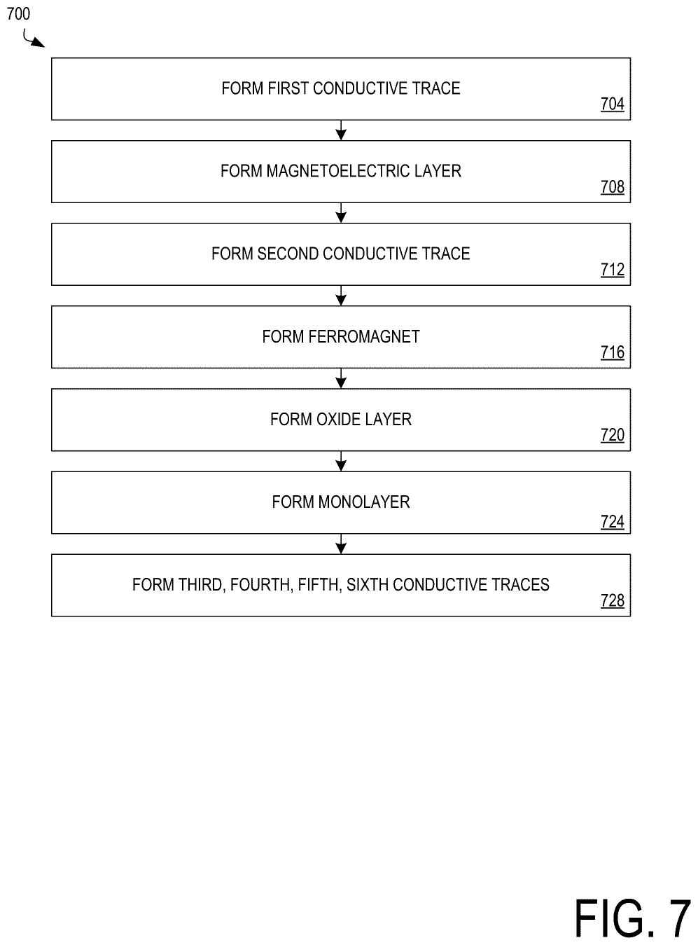

FIGS. 5A-5N and 6A-6N illustrate cross-sectional views of the example valleytronic device illustrated in FIGS. 3A-3C at various stages of fabrication. FIGS. 5A-5N illustrate cross-sectional views of the device 300 along the line A-A′ of FIG. 3A and FIGS. 6A-6N illustrate cross-sectional views of the device 300 along the line B-B′ of FIG. 3A. FIG. 7 illustrates a flowchart of an example method for fabricating the valleytronic MESO device 300.

Any of the valleytronic MESO device fabrication methods described herein, including methods 700 and 1000, may be performed using any suitable microelectronic fabrication techniques. For example, film deposition—such as depositing layers, filling portions of layers (e.g., filling removed portions of layers), and filling via openings—may be performed using any suitable deposition techniques, including, for example, chemical vapor deposition (CVD), metalorganic chemical vapor deposition (MOCVD), molecular beam epitaxy (MBE), atomic layer deposition (ALD), sputtering and/or physical vapor deposition (PVD). Moreover, layer patterning—such as dielectric, ferromagnet, magnetoelectric layer patterning—may be performed using any suitable techniques, such as photolithography-based patterning and etching (e.g., dry etching or wet etching).

At 704 in method 700, the first conductive trace 312a is formed. A layer 301 of conductive material is formed on an inter-layer dielectric (ILD) 303, as shown in FIGS. 5A and 6A. The ILD 303 is located on or above a substrate (not shown). The layer 301 is patterned to form the first conductive trace 312a and a dielectric layer 307 is formed in the regions where the conductive layer 301 was removed, as shown in FIGS. 5B and 6B.

At 708, the magnetoelectric layer 340 is formed. A layer 341 of magnetoelectric material is formed on the dielectric layer 307 and the first conductive 312a, as shown in FIGS. 5C and 6C. The layer 341 is patterned to form the magnetoelectric layer 340, which is positioned adjacent to the first conductive trace 312, and a dielectric layer 320 is formed in the regions where the magnetoelectric layer 341 was removed, as shown in FIGS. 5D and 6D.

At 712, the second conductive trace 352 is formed. The dielectric layer 320 is patterned to form a cavity, as shown in FIGS. 5E and 6E and the second conductive trace 352 is formed in the cavity, as shown in FIGS. 5F and 6F.

At 716, the ferromagnet 302 is formed. A layer of ferromagnetic material 391 is formed on the dielectric layer 320 and the conductive traces 312a and 352, as shown in FIGS. 5G and 6G. The layer of ferromagnetic material 391 is patterned to form the ferromagnet 302 and a dielectric layer 332 is formed in the regions where the layer of ferromagnetic material 391 was removed, as shown in FIGS. 5H and 6H. The ferromagnet 302 has in-plane magnetic anisotropy.

At 720, the oxide layer 344 is formed. An oxide layer 343 is formed on the dielectric layer 332 and the ferromagnet 302, as shown in FIGS. 5I and 6I. The oxide layer 343 is patterned to form the oxide layer 344 and a dielectric layer 336 is formed in the regions where the oxide layer 343 was removed, as shown in FIGS. 5J and 6J. The presence of the oxide layer 344 induces perpendicular magnetic anisotropy in the ferromagnet 302 in the region of the ferromagnet 302 that is positioned adjacent to the oxide layer 344. The portion of the ferromagnet 302 not positioned adjacent to the oxide layer 344 retains its in-plane magnetic anisotropy. After formation of the oxide layer 344, the ferromagnet 302 comprises an IMA ferromagnet 324 and a PMA ferromagnet 328. The ferromagnet 302 extends from the IMA ferromagnet 324 to the PMA ferromagnet 328 along a first axis. The magnetoelectric layer 340 is positioned adjacent to the IMA ferromagnet 324 and the second conductive trace 352 is positioned adjacent to the PMA ferromagnet 328.

At 724, the monolayer 360 is formed. A valleytronic monolayer 359 is formed on the dielectric layer 336 and the oxide layer 344, as shown in FIGS. 5K and 6K. The valleytronic monolayer 359 is patterned to form the valleytronic monolayer 360 and a dielectric layer 346 is formed in the regions where the valleytronic monolayer 359 was removed, as shown in FIGS. 5L and 6L. The valleytronic monolayer extends along a second axis that is substantially orthogonal to the first axis of the ferromagnet 302. The oxide layer 344 is positioned between the valleytronic monolayer 360 and the PMA ferromagnet 328.

At 728, the third, fourth, fifth, and sixth conductive traces 364a, 364b, 312b, and 348 are formed. A dielectric layer 351 is formed on top of the dielectric layer 346 and the valleytronic monolayer 360 and the dielectric layers 351, 346, and 336 are patterned to create holes for conductive traces 364a, 364b, 312b, and 348, as shown in FIGS. 5M and 6M. The conductive traces 364a, 364b, 312b, and 348, are then formed in the cavities, as shown in FIGS. 5N and 6N. The third conductive trace 364a is positioned adjacent to a first surface of the valleytronic monolayer 360 at a first end portion of the monolayer, the fourth conductive trace 364b is positioned adjacent to the first surface of the valleytronic monolayer 360 at a second end portion of the monolayer that is opposite the first end portion of the valleytronic monolayer, the fifth conductive trace 312b is positioned adjacent to the first ferromagnet 324, and the sixth conductive trace 348 is positioned adjacent to the first surface of the valleytronic monolayer and positioned between the third conductive trace 364a and the fourth conductive trace 364b. The second ferromagnet 328 is positioned between the second conductive trace 352 and the sixth conductive trace 348.

At this point, the method 700 may be complete. In some embodiments, however, the method 700 may restart and/or certain elements of the method 700 may be repeated. For example, in some embodiments, the method 700 may restart at 704 to fabricate another valleytronic MESO device with the same or different design on top of valleytronic MESO device 300.

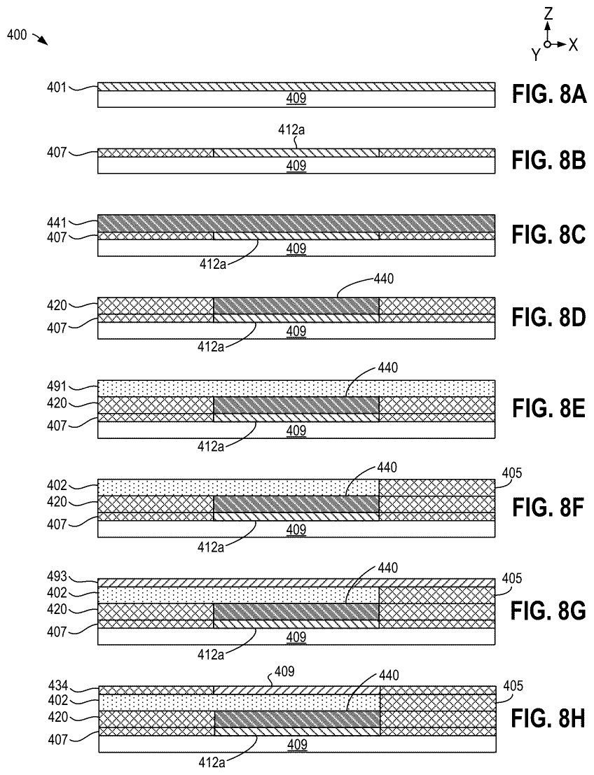

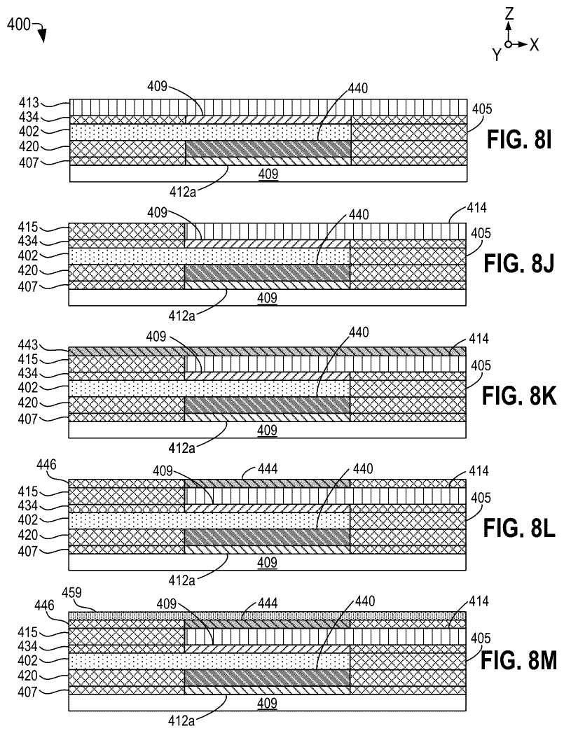

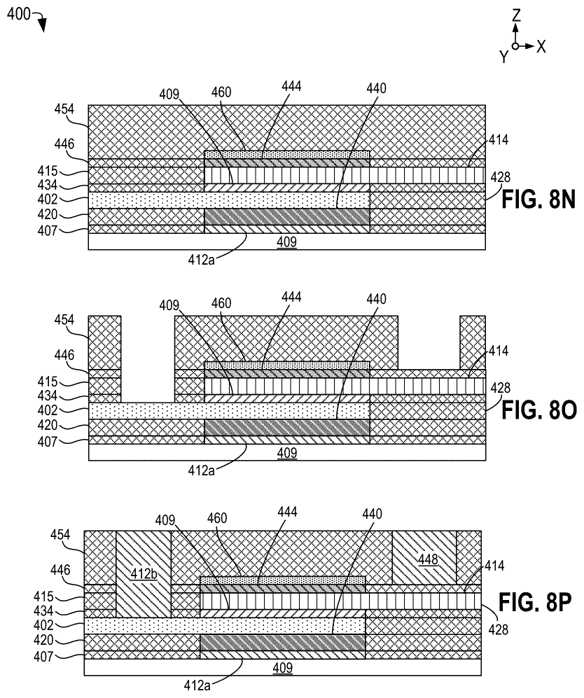

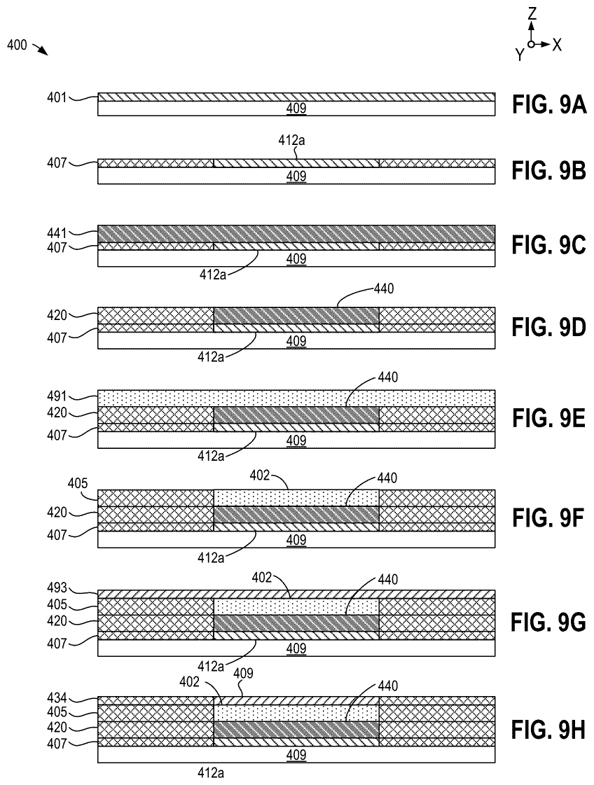

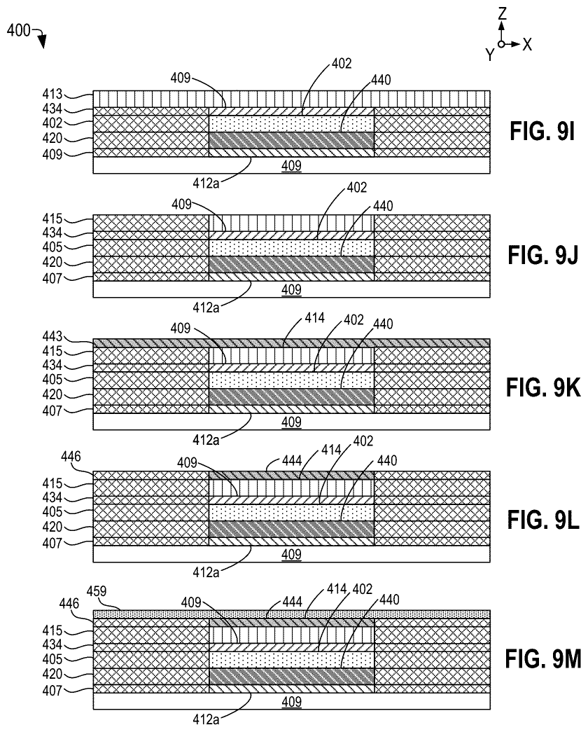

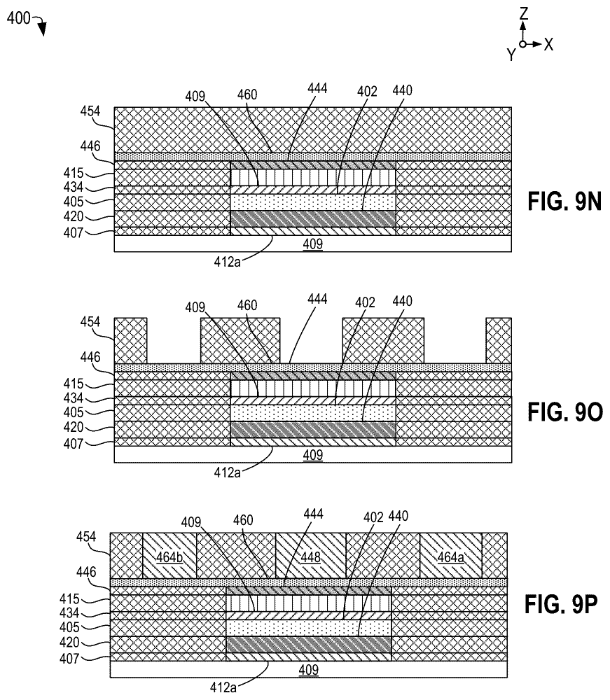

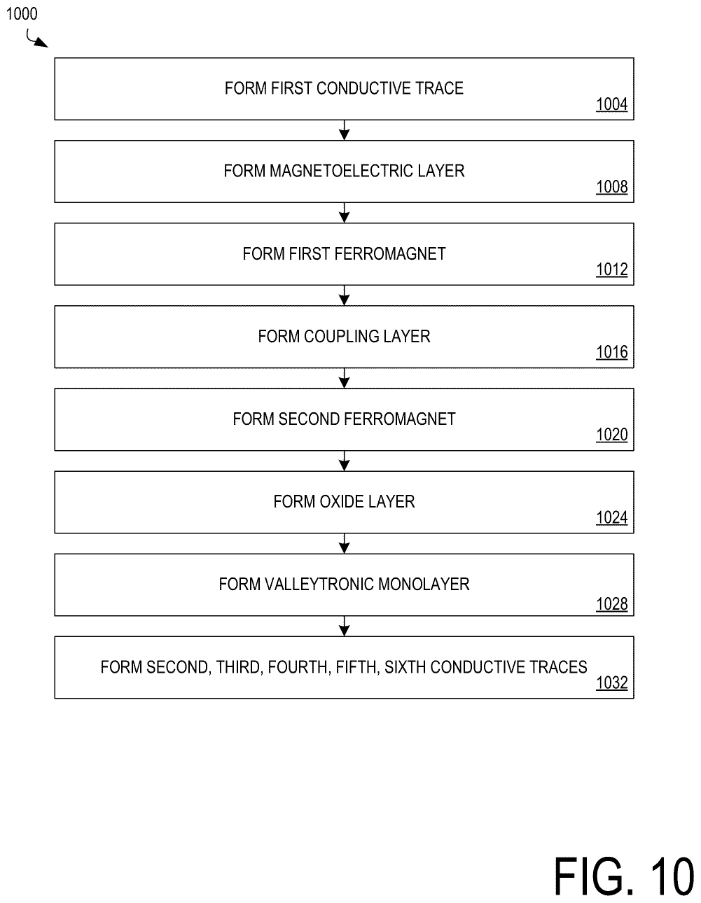

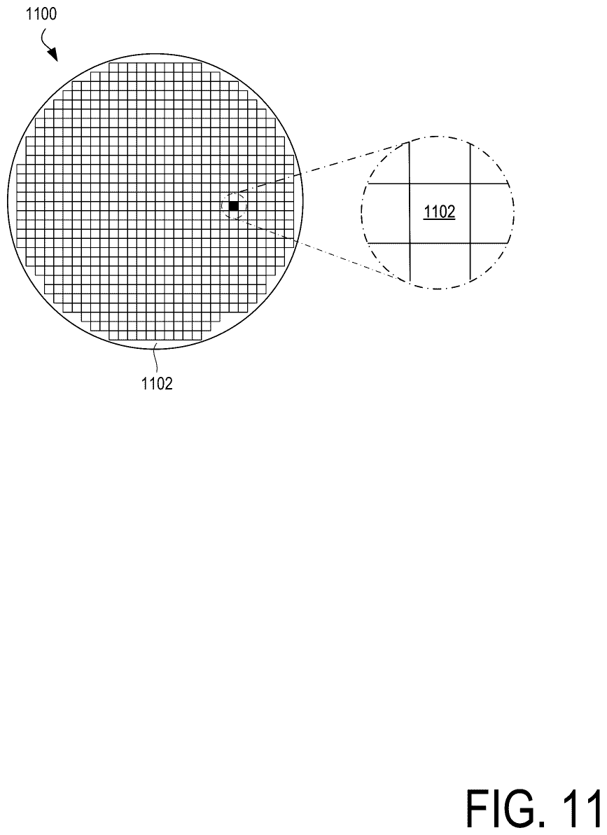

FIGS. 8A-8P and 9A-9P illustrate cross-sectional views of the example valleytronic device of FIGS. 4A-4C at various stages of fabrication. FIGS. 8A-8P illustrate cross-sectional views of the device 400 along the line A-A′ of FIG. 4A and FIGS. 9A-9P illustrate cross-sectional views of the device 400 along the line B-B′ of FIG. 4A. FIG. 10 illustrates a flowchart of an example method for fabricating the valleytronic MESO device 400.

At 1004 in method 1000, the first conductive trace 412a is formed. A layer 401 of conductive material is formed on an inter-layer dielectric (ILD) 409, as shown in FIGS. 8A and 9A. The ILD 409 is located on or above a substrate (not shown). The layer 401 is patterned to form the first conductive trace 412a and a dielectric layer 407 is formed in the regions where the conductive layer 401 was removed, as shown in FIGS. 8B and 9B.

At 1008, the magnetoelectric layer 440 is formed. A layer 441 of magnetoelectric material is formed on the dielectric layer 407 and the first conductive 412a, as shown in FIGS. 8C and 9C. The magnetoelectric layer 441 is patterned to form the magnetoelectric layer 440, which is positioned adjacent to the first conductive trace 412a, and a dielectric layer 420 is formed in the regions where the magnetoelectric layer 441 was removed, as shown in FIGS. 8D and 9D.

At 1012, the first ferromagnet 402 is formed. A layer 491 of ferromagnetic material is formed on the dielectric layer 420 and the magnetoelectric layer 440, as shown in FIGS. 8E and 9E. The layer 491 is patterned to form the first ferromagnet 402, a portion of which is positioned adjacent to the magnetoelectric layer 440, and a dielectric layer 405 is formed in the regions where the layer of ferromagnetic material 491 was removed, as shown in FIGS. 8F and 9F. The magnetoelectric layer 440 is positioned between a portion of the first ferromagnet 402 and the first conductive trace 412a. The first ferromagnet 402 possesses in-plane magnetic anisotropy.

At 1016, the coupling layer 403 is formed. A layer 493 is formed on the first ferromagnet 402 and the dielectric layer 405, as shown in FIGS. 8G and 9G. The layer 493 is patterned to form the coupling layer 403, a portion of which is positioned adjacent to the first ferromagnet 402, and a dielectric layer 434 is formed in the regions where layer 493 was removed, as shown in FIGS. 8H and 9H.

At 1020, the second ferromagnet 414 is formed. A layer of ferromagnetic material 413 is formed on the coupling layer 403 and the dielectric layer 434, as shown in FIGS. 8I and 9I. The layer of ferromagnetic material 413 is patterned to form the second ferromagnet 414, which is positioned adjacent to the coupling layer 403, and a dielectric layer 415 is formed in the regions where the layer of ferromagnetic material 413 was removed, as shown in FIGS. 8J and 9J. The second ferromagnet 414 extends lengthwise along a first axis and possesses in-plane magnetic anisotropy in its as-formed state. The second ferromagnet 414 is positioned adjacent to the coupling layer 403 and the coupling layer 403 is positioned between the first ferromagnet 402 and the second ferromagnet 414.

At 1024, the oxide layer 444 is formed. An oxide layer 443 is formed on the second ferromagnet 414 and the dielectric layer 415, as shown in FIGS. 8K and 9K. The layer 443 is patterned to form the oxide layer 444, a portion of which is positioned adjacent to the second ferromagnet 414, and a dielectric layer 446 is formed in the regions where the oxide layer 443 was removed, as shown in FIGS. 8L and 9L. The presence of the oxide layer 444 positioned adjacent to the second ferromagnet 414 induces perpendicular magnetic anisotropy in the second ferromagnet 414.

At 1028, the valleytronic monolayer 460 is formed. A valleytronic monolayer 459 is formed on the oxide layer 444 and the dielectric layer 446, as shown in FIGS. 8M and 9M. The valleytronic monolayer 459 is patterned to form the valleytronic monolayer 460, which is positioned adjacent to the oxide layer 444, and a dielectric layer 454 is formed in the regions where the valleytronic monolayer 459 was removed as well as over the valleytronic monolayer 460, as shown in FIGS. 8N and 9N. The monolayer extends along a second axis that is substantially orthogonal to the first axis of the second ferromagnet 414. The valleytronic monolayer 460 is positioned adjacent to the oxide layer 444 and the oxide layer 44 is positioned between the valleytronic monolayer 460 and the second ferromagnet 414.

At 1032, the second, third, fourth, fifth, and sixth conductive traces 412b, 464a, 464b, 452, and 448 are formed. A dielectric layer 454 is formed on top of the dielectric layer 446 and the valleytronic monolayer 460, as shown in FIGS. 8N and 9N. The dielectric layers 454, 414, and 434 are then patterned to create holes for conductive traces 412b, 464a, 464b, 452, and 448, as shown in FIGS. 8O and 9O. The conductive traces 412b, 464a, 464b, 452, and 448, are then formed in the cavities, as shown in FIGS. 8P and 9P. The second conductive trace 412b is positioned adjacent to the first ferromagnet 402, the third conductive trace 464a is positioned adjacent to a first surface of the valleytronic monolayer 460 at a first end portion of the valleytronic monolayer 460, the fourth conductive trace 464b is positioned adjacent to the first surface of the valleytronic monolayer at a second end portion of the monolayer that is opposite the first end portion of valleytronic monolayer 460, the fifth conductive trace 452 is positioned adjacent to the second ferromagnet 414, and the sixth conductive trace 448 is positioned adjacent to the first surface of the valleytronic monolayer and positioned between the third conductive trace 464a and the fourth conductive trace 464b. At least a portion of the valleytronic monolayer 460 is positioned between the second ferromagnet 414 and the sixth conductive trace.

At this point, the method 1000 may be complete. In some embodiments, however, the method 1000 may restart and/or certain elements of the method 1000 may be repeated. For example, in some embodiments, the method 1000 may restart at 1004 to fabricate another valleytronic MESO device with the same or different design on top of valleytronic MESO device 400.

In some embodiments, the method 1000 does not comprise forming the oxide layer and the second ferromagnet 414 has perpendicular magnetic anisotropy in its as-formed state. That is, the second ferromagnet 414 does not require the presence of an oxide layer positioned adjacent to it to cause the second ferromagnet 414 to exhibit perpendicular magnetic anisotropy.

The valleytronic MESO devices described herein can be used in any processor unit or integrated circuit component described or referenced herein. An integrated circuit component comprising valleytronic MESO devices can be attached to a printed circuit board (motherboard, mainboard). In some embodiments, one or more additional integrated circuit components or other components (e.g., battery, antenna) can be attached to the printed circuit board. In some embodiments, the printed circuit board and the integrated circuit component can be located in a computing device that comprises a housing that encloses the printed circuit board and the integrated circuit component.

The valleytronic MESO devices can be fabricated as part of an integrated circuit structure. The integrated circuit structure can comprise a die substrate, such as a die substrate comprising silicon, and one or more interconnect layers. The integrated circuit structure can comprise other types of devices, such as electronic transistors (transistors such as CMOS transistors that operate through control of the flow of electric current). A valleytronic MESO device can connect to other valleytronic MESO devices or other types of devices in the integrated circuit structure by one or more interconnect layers (and vias) or by being directly connected to another valleytronic MESO device or another device type.

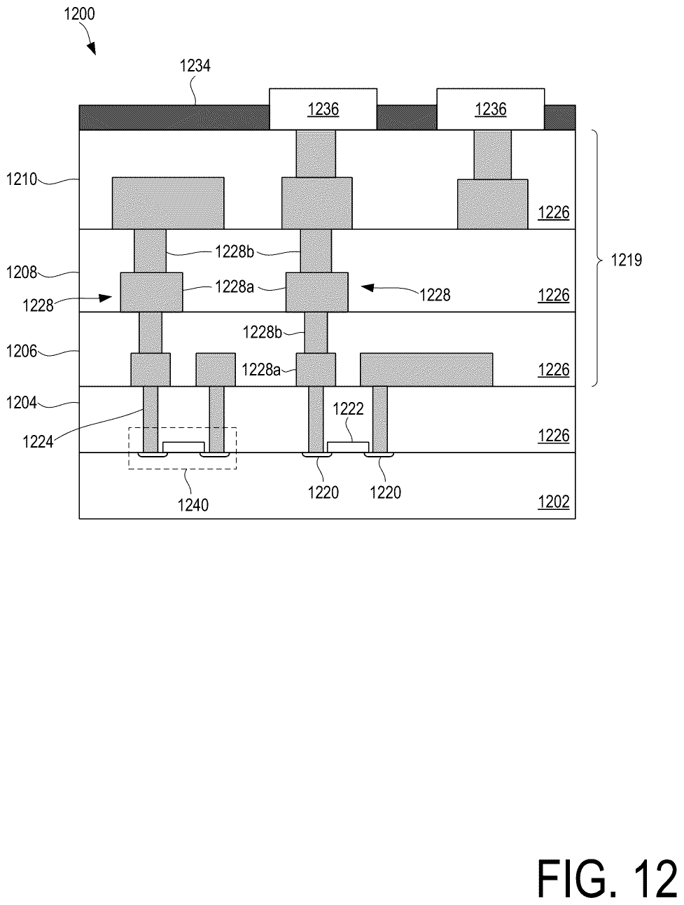

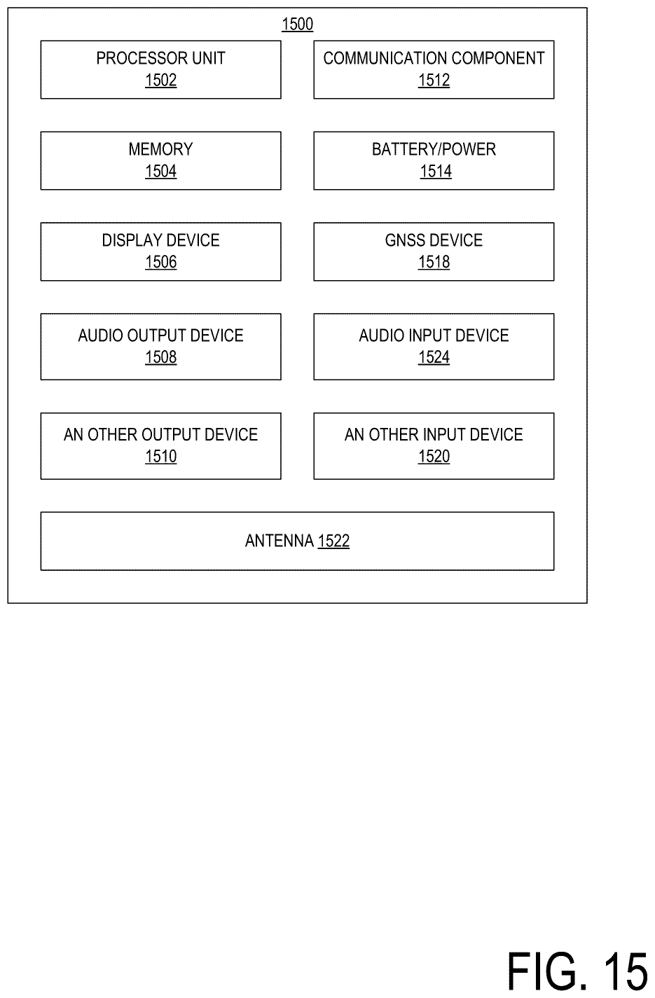

FIG. 11 is a top view of a wafer 1100 and dies 1102 on which any of the valleytronic MESO devices disclosed herein may be fabricated. The wafer 1100 may be composed of semiconductor material and may include one or more dies 1102 having integrated circuit structures formed on a surface of the wafer 1100. The individual dies 1102 may be a repeating unit of an integrated circuit product that includes any suitable integrated circuit. After the fabrication of the semiconductor product is complete, the wafer 1100 may undergo a singulation process in which the dies 1102 are separated from one another to provide discrete “chips” of the integrated circuit product. The die 1102 may include one or more transistors (e.g., some of the transistors 1240 of FIG. 12, discussed below), supporting circuitry to route electrical signals to the transistors, passive components (e.g., signal traces, resistors, capacitors, or inductors), and/or any other integrated circuit components. In some embodiments, the wafer 1100 or the die 1102 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1102. For example, a memory array formed by multiple memory devices may be formed on a same die 1102 as a processor unit (e.g., the processor unit 1502 of FIG. 15) or other logic that is configured to store information in the memory devices or execute instructions stored in the memory array. Various ones of the microelectronic assemblies disclosed herein may be manufactured using a die-to-wafer assembly technique in which some dies are attached to a wafer 1100 that include others of the dies, and the wafer 1100 is subsequently singulated.

FIG. 12 is a cross-sectional side view of an integrated circuit device 1200 that may be included in any of the microelectronic assemblies disclosed herein (e.g., in any of the dies disclosed herein). One or more of the integrated circuit devices 1200 may be included in one or more dies 1202 (FIG. 11). The integrated circuit device 1200 may be formed on a die substrate 1202 (e.g., the wafer 1100 of FIG. 11) and may be included in a die (e.g., the die 1102 of FIG. 11). The die substrate 1202 may be a semiconductor substrate composed of semiconductor material systems including, for example, n-type or p-type materials systems (or a combination of both). The die substrate 1202 may include, for example, a crystalline substrate formed using a bulk silicon or a silicon-on-insulator (SOI) substructure. In some embodiments, the die substrate 1202 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 1202. Although a few examples of materials from which the die substrate 1202 may be formed are described here, any material that may serve as a foundation for an integrated circuit device 1200 may be used. The die substrate 1202 may be part of a singulated die (e.g., the dies 1102 of FIG. 11) or a wafer (e.g., the wafer 1100 of FIG. 11).

The integrated circuit device 1200 may include one or more device layers 1204 disposed on the die substrate 1202. The device layer 1204 may include features of one or more transistors 1240 (e.g., metal oxide semiconductor field-effect transistors (MOSFETs)) formed on the die substrate 1202. The transistors 1240 may include, for example, one or more source and/or drain (S/D) regions 1220, a gate 1222 to control current flow between the S/D regions 1220, and one or more S/D contacts 1224 to route electrical signals to/from the S/D regions 1220. The transistors 1240 may include additional features not depicted for the sake of clarity, such as device isolation regions, gate contacts, and the like. The transistors 1240 are not limited to the type and configuration depicted in FIG. 12 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

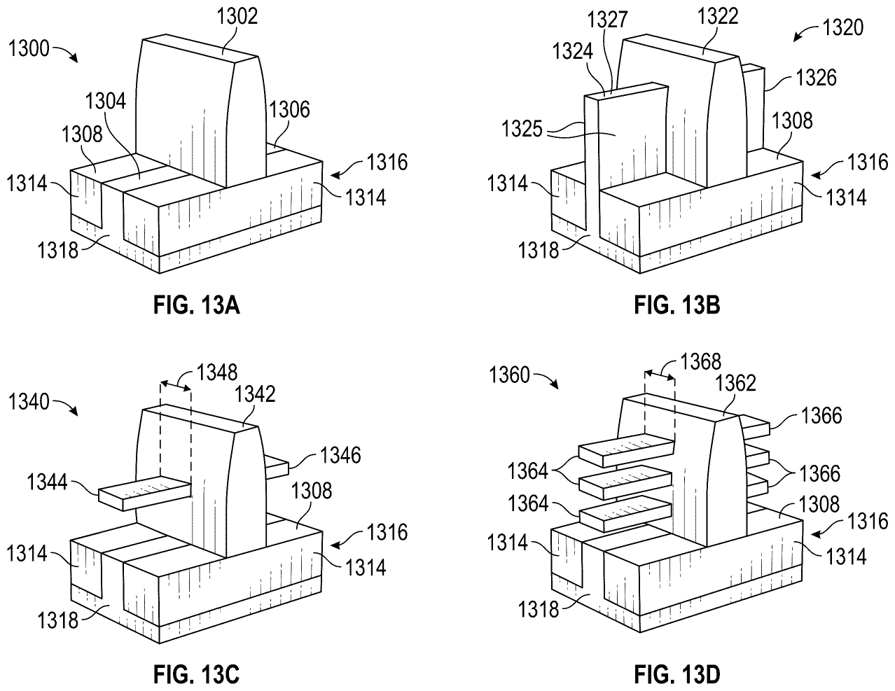

FIGS. 13A-13D are simplified perspective views of example planar, FinFET, gate-all-around, and stacked gate-all-around transistors. The transistors illustrated in FIGS. 13A-13D are formed on a substrate 1316 having a surface 1308. Isolation regions 1314 separate the source and drain regions of the transistors from other transistors and from a bulk region 1318 of the substrate 1316.

FIG. 13A is a perspective view of an example planar transistor 1300 comprising a gate 1302 that controls current flow between a source region 1304 and a drain region 1306. The transistor 1300 is planar in that the source region 1304 and the drain region 1306 are planar with respect to the substrate surface 1308.

FIG. 13B is a perspective view of an example FinFET transistor 1320 comprising a gate 1322 that controls current flow between a source region 1324 and a drain region 1326. The transistor 1320 is non-planar in that the source region 1324 and the drain region 1326 comprise “fins” that extend upwards from the substrate surface 1328. As the gate 1322 encompasses three sides of the semiconductor fin that extends from the source region 1324 to the drain region 1326, the transistor 1320 can be considered a tri-gate transistor. FIG. 13B illustrates one S/D fin extending through the gate 1322, but multiple S/D fins can extend through the gate of a FinFET transistor.

FIG. 13C is a perspective view of a gate-all-around (GAA) transistor 1340 comprising a gate 1342 that controls current flow between a source region 1344 and a drain region 1346. The transistor 1340 is non-planar in that the source region 1344 and the drain region 1346 are elevated from the substrate surface 1328.

FIG. 13D is a perspective view of a GAA transistor 1360 comprising a gate 1362 that controls current flow between multiple elevated source regions 1364 and multiple elevated drain regions 1366. The transistor 1360 is a stacked GAA transistor as the gate controls the flow of current between multiple elevated S/D regions stacked on top of each other. The transistors 1340 and 1360 are considered gate-all-around transistors as the gates encompass all sides of the semiconductor portions that extends from the source regions to the drain regions. The transistors 1340 and 1360 can alternatively be referred to as nanowire, nanosheet, or nanoribbon transistors depending on the width (e.g., widths 1348 and 1368 of transistors 1340 and 1360, respectively) of the semiconductor portions extending through the gate.

Returning to FIG. 12, a transistor 1240 may include a gate 1222 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 1240 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1240 along the source-channel-drain direction, the gate electrode may consist of a U-shaped structure that includes a bottom portion substantially parallel to the surface of the die substrate 1202 and two sidewall portions that are substantially perpendicular to the top surface of the die substrate 1202. In other embodiments, at least one of the metal layers that form the gate electrode may simply be a planar layer that is substantially parallel to the top surface of the die substrate 1202 and does not include sidewall portions substantially perpendicular to the top surface of the die substrate 1202. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1220 may be formed within the die substrate 1202 adjacent to the gate 1222 of individual transistors 1240. The S/D regions 1220 may be formed using an implantation/diffusion process or an etching/deposition process, for example. In the former process, dopants such as boron, aluminum, antimony, phosphorous, or arsenic may be ion-implanted into the die substrate 1202 to form the S/D regions 1220. An annealing process that activates the dopants and causes them to diffuse farther into the die substrate 1202 may follow the ion-implantation process. In the latter process, the die substrate 1202 may first be etched to form recesses at the locations of the S/D regions 1220. An epitaxial deposition process may then be carried out to fill the recesses with material that is used to fabricate the S/D regions 1220. In some implementations, the S/D regions 1220 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1220 may be formed using one or more alternate semiconductor materials such as germanium or a group III-V material or alloy. In further embodiments, one or more layers of metal and/or metal alloys may be used to form the S/D regions 1220.

Electrical signals, such as power and/or input/output (I/O) signals, may be routed to and/or from the devices (e.g., transistors 1240) of the device layer 1204 through one or more interconnect layers disposed on the device layer 1204 (illustrated in FIG. 12 as interconnect layers 1206-1210). For example, electrically conductive features of the device layer 1204 (e.g., the gate 1222 and the S/D contacts 1224) may be electrically coupled with the interconnect structures 1228 of the interconnect layers 1206-1210. The one or more interconnect layers 1206-1210 may form a metallization stack (also referred to as an “ILD stack”) 1219 of the integrated circuit device 1200.

The interconnect structures 1228 may be arranged within the interconnect layers 1206-1210 to route electrical signals according to a wide variety of designs; in particular, the arrangement is not limited to the particular configuration of interconnect structures 1228 depicted in FIG. 12. Although a particular number of interconnect layers 1206-1210 is depicted in FIG. 12, embodiments of the present disclosure include integrated circuit devices having more or fewer interconnect layers than depicted.

In some embodiments, the interconnect structures 1228 may include lines 1228a and/or vias 1228b filled with an electrically conductive material such as a metal. The lines 1228a may be arranged to route electrical signals in a direction of a plane that is substantially parallel with a surface of the die substrate 1202 upon which the device layer 1204 is formed. For example, the lines 1228a may route electrical signals in a direction in and out of the page and/or in a direction across the page from the perspective of FIG. 12 The vias 1228b may be arranged to route electrical signals in a direction of a plane that is substantially perpendicular to the surface of the die substrate 1202 upon which the device layer 1204 is formed. In some embodiments, the vias 1228b may electrically couple lines 1228a of different interconnect layers 1206-1210 together.

The interconnect layers 1206-1210 may include a dielectric material 1226 disposed between the interconnect structures 1228, as shown in FIG. 12. In some embodiments, dielectric material 1226 disposed between the interconnect structures 1228 in different ones of the interconnect layers 1206-1210 may have different compositions; in other embodiments, the composition of the dielectric material 1226 between different interconnect layers 1206-1210 may be the same. The device layer 1204 may include a dielectric material 1226 disposed between the transistors 1240 and a bottom layer of the metallization stack as well. The dielectric material 1226 included in the device layer 1204 may have a different composition than the dielectric material 1226 included in the interconnect layers 1206-1210; in other embodiments, the composition of the dielectric material 1226 in the device layer 1204 may be the same as a dielectric material 1226 included in any one of the interconnect layers 1206-1210.

A first interconnect layer 1206 (referred to as Metal 1 or “M1”) may be formed directly on the device layer 1204. In some embodiments, the first interconnect layer 1206 may include lines 1228a and/or vias 1228b, as shown. The lines 1228a of the first interconnect layer 1206 may be coupled with contacts (e.g., the S/D contacts 1224) of the device layer 1204. The vias 1228b of the first interconnect layer 1206 may be coupled with the lines 1228a of a second interconnect layer 1208.

The second interconnect layer 1208 (referred to as Metal 2 or “M2”) may be formed directly on the first interconnect layer 1206. In some embodiments, the second interconnect layer 1208 may include via 1228b to couple the lines 1228 of the second interconnect layer 1208 with the lines 1228a of a third interconnect layer 1210. Although the lines 1228a and the vias 1228b are structurally delineated with a line within individual interconnect layers for the sake of clarity, the lines 1228a and the vias 1228b may be structurally and/or materially contiguous (e.g., simultaneously filled during a dual-damascene process) in some embodiments.

The third interconnect layer 1210 (referred to as Metal 3 or “M3”) (and additional interconnect layers, as desired) may be formed in succession on the second interconnect layer 1208 according to similar techniques and configurations described in connection with the second interconnect layer 1208 or the first interconnect layer 1206. In some embodiments, the interconnect layers that are “higher up” in the metallization stack 1219 in the integrated circuit device 1200 (i.e., farther away from the device layer 1204) may be thicker that the interconnect layers that are lower in the metallization stack 1219, with lines 1228a and vias 1228b in the higher interconnect layers being thicker than those in the lower interconnect layers.

The integrated circuit device 1200 may include a solder resist material 1234 (e.g., polyimide or similar material) and one or more conductive contacts 1236 formed on the interconnect layers 1206-1210. In FIG. 12, the conductive contacts 1236 are illustrated as taking the form of bond pads. The conductive contacts 1236 may be electrically coupled with the interconnect structures 1228 and configured to route the electrical signals of the transistor(s) 1240 to external devices. For example, solder bonds may be formed on the one or more conductive contacts 1236 to mechanically and/or electrically couple an integrated circuit die including the integrated circuit device 1200 with another component (e.g., a printed circuit board). The integrated circuit device 1200 may include additional or alternate structures to route the electrical signals from the interconnect layers 1206-1210; for example, the conductive contacts 1236 may include other analogous features (e.g., posts) that route the electrical signals to external components.

In some embodiments in which the integrated circuit device 1200 is a double-sided die, the integrated circuit device 1200 may include another metallization stack (not shown) on the opposite side of the device layer(s) 1204. This metallization stack may include multiple interconnect layers as discussed above with reference to the interconnect layers 1206-1210, to provide conductive pathways (e.g., including conductive lines and vias) between the device layer(s) 1204 and additional conductive contacts (not shown) on the opposite side of the integrated circuit device 1200 from the conductive contacts 1236.

In other embodiments in which the integrated circuit device 1200 is a double-sided die, the integrated circuit device 1200 may include one or more through silicon vias (TSVs) through the die substrate 1202; these TSVs may make contact with the device layer(s) 1204, and may provide conductive pathways between the device layer(s) 1204 and additional conductive contacts (not shown) on the opposite side of the integrated circuit device 1200 from the conductive contacts 1236. In some embodiments, TSVs extending through the substrate can be used for routing power and ground signals from conductive contacts on the opposite side of the integrated circuit device 1200 from the conductive contacts 1236 to the transistors 1240 and any other components integrated into the die 1200, and the metallization stack 1219 can be used to route I/O signals from the conductive contacts 1236 to transistors 1240 and any other components integrated into the die 1200.

Multiple integrated circuit devices 1200 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

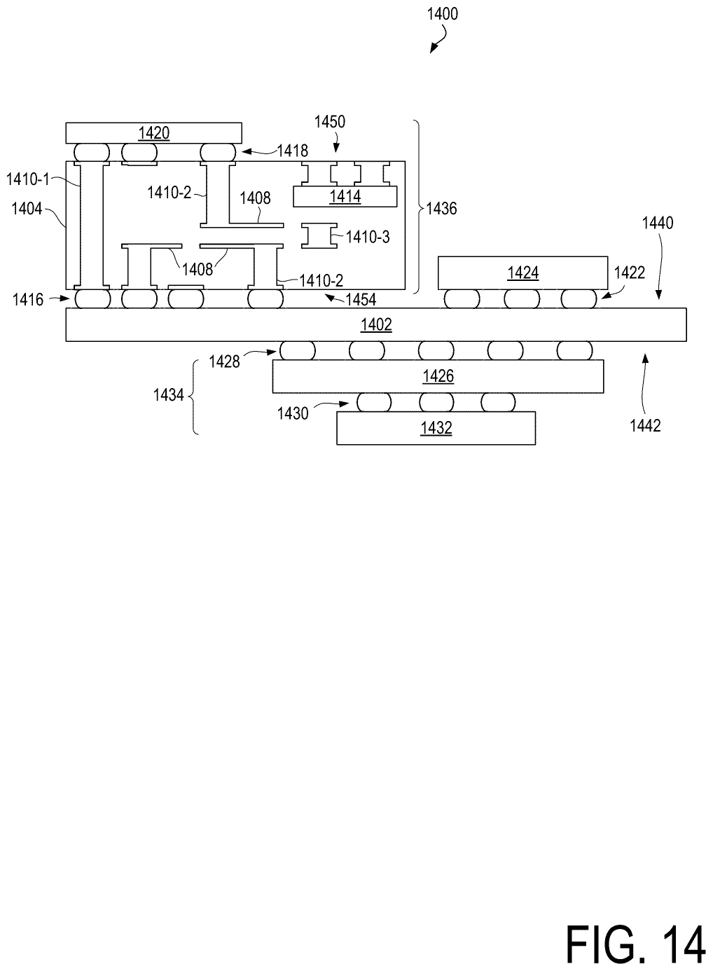

FIG. 14 is a cross-sectional side view of an integrated circuit device assembly 1400 that may include any of the microelectronic assemblies comprising any of the valleytronic MESO devices disclosed herein. In some embodiments, the integrated circuit device assembly 1400 may be a microelectronic assembly. The integrated circuit device assembly 1400 includes a number of components disposed on a circuit board 1402 (which may be a motherboard, system board, mainboard, etc.). The integrated circuit device assembly 1400 includes components disposed on a first face 1440 of the circuit board 1402 and an opposing second face 1442 of the circuit board 1402; generally, components may be disposed on one or both faces 1440 and 1442. Any of the integrated circuit components discussed below with reference to the integrated circuit device assembly 1400 may take the form of any suitable ones of the embodiments of the microelectronic assemblies disclosed herein.

In some embodiments, the circuit board 1402 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1402. In other embodiments, the circuit board 1402 may be a non-PCB substrate. The integrated circuit device assembly 1400 illustrated in FIG. 14 includes a package-on-interposer structure 1436 coupled to the first face 1440 of the circuit board 1402 by coupling components 1416. The coupling components 1416 may electrically and mechanically couple the package-on-interposer structure 1436 to the circuit board 1402, and may include solder balls (as shown in FIG. 14), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 1436 may include an integrated circuit component 1420 coupled to an interposer 1404 by coupling components 1418. The coupling components 1418 may take any suitable form for the application, such as the forms discussed above with reference to the coupling components 1416. Although a single integrated circuit component 1420 is shown in FIG. 14, multiple integrated circuit components may be coupled to the interposer 1404; indeed, additional interposers may be coupled to the interposer 1404. The interposer 1404 may provide an intervening substrate used to bridge the circuit board 1402 and the integrated circuit component 1420.

The integrated circuit component 1420 may be a packaged or unpacked integrated circuit product that includes one or more integrated circuit dies (e.g., the die 1402 of FIG. 14, the integrated circuit device 1400 of FIG. 14) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 1420, a single monolithic integrated circuit die comprises solder bumps attached to contacts on the die. The solder bumps allow the die to be directly attached to the interposer 1404. The integrated circuit component 1420 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 1420 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 1420 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 1420 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 1404 may spread connections to a wider pitch or reroute a connection to a different connection. For example, the interposer 1404 may couple the integrated circuit component 1420 to a set of ball grid array (BGA) conductive contacts of the coupling components 1416 for coupling to the circuit board 1402. In the embodiment illustrated in FIG. 14, the integrated circuit component 1420 and the circuit board 1402 are attached to opposing sides of the interposer 1404; in other embodiments, the integrated circuit component 1420 and the circuit board 1402 may be attached to a same side of the interposer 1404. In some embodiments, three or more components may be interconnected by way of the interposer 1404.

In some embodiments, the interposer 1404 may be formed as a PCB, including multiple metal layers separated from one another by layers of dielectric material and interconnected by electrically conductive vias. In some embodiments, the interposer 1404 may be formed of an epoxy resin, a fiberglass-reinforced epoxy resin, an epoxy resin with inorganic fillers, a ceramic material, or a polymer material such as polyimide. In some embodiments, the interposer 1404 may be formed of alternate rigid or flexible materials that may include the same materials described above for use in a semiconductor substrate, such as silicon, germanium, and other group III-V and group IV materials. The interposer 1404 may include metal interconnects 1408 and vias 1410, including but not limited to through hole vias 1410-1 (that extend from a first face 1450 of the interposer 1404 to a second face 1454 of the interposer 1404), blind vias 1410-2 (that extend from the first or second faces 1450 or 1454 of the interposer 1404 to an internal metal layer), and buried vias 1410-3 (that connect internal metal layers).

In some embodiments, the interposer 1404 can comprise a silicon interposer. Through silicon vias (TSV) extending through the silicon interposer can connect connections on a first face of a silicon interposer to an opposing second face of the silicon interposer. In some embodiments, an interposer 1404 comprising a silicon interposer can further comprise one or more routing layers to route connections on a first face of the interposer 1404 to an opposing second face of the interposer 1404.

The interposer 1404 may further include embedded devices 1414, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1404. The package-on-interposer structure 1436 may take the form of any of the package-on-interposer structures known in the art. In embodiments where the interposer is a non-printed circuit board

The integrated circuit device assembly 1400 may include an integrated circuit component 1424 coupled to the first face 1440 of the circuit board 1402 by coupling components 1422. The coupling components 1422 may take the form of any of the embodiments discussed above with reference to the coupling components 1416, and the integrated circuit component 1424 may take the form of any of the embodiments discussed above with reference to the integrated circuit component 1420.

The integrated circuit device assembly 1400 illustrated in FIG. 14 includes a package-on-package structure 1434 coupled to the second face 1442 of the circuit board 1402 by coupling components 1428. The package-on-package structure 1434 may include an integrated circuit component 1426 and an integrated circuit component 1432 coupled together by coupling components 1430 such that the integrated circuit component 1426 is disposed between the circuit board 1402 and the integrated circuit component 1432. The coupling components 1428 and 1430 may take the form of any of the embodiments of the coupling components 1416 discussed above, and the integrated circuit components 1426 and 1432 may take the form of any of the embodiments of the integrated circuit component 1420 discussed above. The package-on-package structure 1434 may be configured in accordance with any of the package-on-package structures known in the art.

FIG. 15 is a block diagram of an example electrical device 1500 that may include one or more of the microelectronic assemblies disclosed herein. For example, any suitable ones of the components of the electrical device 1500 may include one or more of the integrated circuit device assemblies 1500, integrated circuit components 1520, integrated circuit devices 1500, or integrated circuit dies 1502 disclosed herein, and may be arranged in any of the microelectronic assemblies disclosed herein. A number of components are illustrated in FIG. 15 as included in the electrical device 1500, but any one or more of these components may be omitted or duplicated, as suitable for the application. In some embodiments, some or all of the components included in the electrical device 1500 may be attached to one or more motherboards mainboards, or system boards. In some embodiments, one or more of these components are fabricated onto a single system-on-a-chip (SoC) die.

Additionally, in various embodiments, the electrical device 1500 may not include one or more of the components illustrated in FIG. 15, but the electrical device 1500 may include interface circuitry for coupling to the one or more components. For example, the electrical device 1500 may not include a display device 1506, but may include display device interface circuitry (e.g., a connector and driver circuitry) to which a display device 1506 may be coupled. In another set of examples, the electrical device 1500 may not include an audio input device 1524 or an audio output device 1508, but may include audio input or output device interface circuitry (e.g., connectors and supporting circuitry) to which an audio input device 1524 or audio output device 1508 may be coupled.

The electrical device 1500 may include one or more processor units 1502 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1502 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1500 may include a memory 1504, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1504 may include memory that is located on the same integrated circuit die as the processor unit 1502. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 1500 can comprise one or more processor units 1502 that are heterogeneous or asymmetric to another processor unit 1502 in the electrical device 1500. There can be a variety of differences between the processing units 1502 in a system in terms of a spectrum of metrics of merit including architectural, microarchitectural, thermal, power consumption characteristics, and the like. These differences can effectively manifest themselves as asymmetry and heterogeneity among the processor units 1502 in the electrical device 1500.

In some embodiments, the electrical device 1500 may include a communication component 1512 (e.g., one or more communication components). For example, the communication component 1512 can manage wireless communications for the transfer of data to and from the electrical device 1500. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1512 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1512 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1512 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1512 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1512 may operate in accordance with other wireless protocols in other embodiments. The electrical device 1500 may include an antenna 1522 to facilitate wireless communications and/or to receive other wireless communications (such as AM or FM radio transmissions).

In some embodiments, the communication component 1512 may manage wired communications, such as electrical, optical, or any other suitable communication protocols (e.g., IEEE 802.3 Ethernet standards). As noted above, the communication component 1512 may include multiple communication components. For instance, a first communication component 1512 may be dedicated to shorter-range wireless communications such as Wi-Fi or Bluetooth, and a second communication component 1512 may be dedicated to longer-range wireless communications such as global positioning system (GPS), EDGE, GPRS, CDMA, WiMAX, LTE, EV-DO, or others. In some embodiments, a first communication component 1512 may be dedicated to wireless communications, and a second communication component 1512 may be dedicated to wired communications.

The electrical device 1500 may include battery/power circuitry 1514. The battery/power circuitry 1514 may include one or more energy storage devices (e.g., batteries or capacitors) and/or circuitry for coupling components of the electrical device 1500 to an energy source separate from the electrical device 1500 (e.g., AC line power).

The electrical device 1500 may include a display device 1506 (or corresponding interface circuitry, as discussed above). The display device 1506 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1500 may include an audio output device 1508 (or corresponding interface circuitry, as discussed above). The audio output device 1508 may include any embedded or wired or wirelessly connected external device that generates an audible indicator, such speakers, headsets, or earbuds.

The electrical device 1500 may include an audio input device 1524 (or corresponding interface circuitry, as discussed above). The audio input device 1524 may include any embedded or wired or wirelessly connected device that generates a signal representative of a sound, such as microphones, microphone arrays, or digital instruments (e.g., instruments having a musical instrument digital interface (MIDI) output). The electrical device 1500 may include a Global Navigation Satellite System (GNSS) device 1518 (or corresponding interface circuitry, as discussed above), such as a Global Positioning System (GPS) device. The GNSS device 1518 may be in communication with a satellite-based system and may determine a geolocation of the electrical device 1500 based on information received from one or more GNSS satellites, as known in the art.

The electrical device 1500 may include an other output device 1510 (or corresponding interface circuitry, as discussed above). Examples of the other output device 1510 may include an audio codec, a video codec, a printer, a wired or wireless transmitter for providing information to other devices, or an additional storage device.

The electrical device 1500 may include an other input device 1520 (or corresponding interface circuitry, as discussed above). Examples of the other input device 1520 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1500 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1500 may be any other electronic device that processes data. In some embodiments, the electrical device 1500 may comprise multiple discrete physical components. Given the range of devices that the electrical device 1500 can be manifested as in various embodiments, in some embodiments, the electrical device 1500 can be referred to as a computing device or a computing system.

As used in this application and the claims, a list of items joined by the term “and/or” can mean any combination of the listed items. For example, the phrase “A, B and/or C” can mean A; B; C; A and B; A and C; B and C; or A, B and C. As used in this application and the claims, a list of items joined by the term “at least one of” can mean any combination of the listed terms. For example, the phrase “at least one of A, B or C” can mean A; B; C; A and B; A and C; B and C; or A, B, and C. Moreover, as used in this application and the claims, a list of items joined by the term “one or more of” can mean any combination of the listed terms. For example, the phrase “one or more of A, B and C” can mean A; B; C; A and B; A and C; B and C; or A, B, and C.

As used in this application and the claims, the phrase “individual of” or “respective of” following by a list of items recited or stated as having a trait, feature, etc. means that all of the items in the list possess the stated or recited trait, feature, etc. For example, the phrase “individual of A, B, or C, comprise a sidewall” or “respective of A, B, or C, comprise a sidewall” means that A comprises a sidewall, B comprises sidewall, and C comprises a sidewall.

The disclosed methods, apparatuses, and systems are not to be construed as limiting in any way. Instead, the present disclosure is directed toward all novel and nonobvious features and aspects of the various disclosed embodiments, alone and in various combinations and subcombinations with one another. The disclosed methods, apparatuses, and systems are not limited to any specific aspect or feature or combination thereof, nor do the disclosed embodiments require that any one or more specific advantages be present or problems be solved.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

The following examples pertain to additional embodiments of technologies disclosed herein.

Example 1 is an apparatus comprising: a ferromagnetic layer comprising a first portion and a second portion, the ferromagnetic layer extending from the first portion to the second portion along a first axis; a magnetoelectric layer; a monolayer extending along a second axis substantially orthogonal to the first axis; and an oxide layer positioned adjacent to the second portion of the ferromagnetic layer, the magnetoelectric layer positioned adjacent to the first portion of the ferromagnetic layer, the oxide layer positioned between the second portion of the ferromagnetic layer and the monolayer, the oxide layer comprising oxygen.

Example 2 comprises the apparatus of Example 1, wherein the ferromagnetic layer comprises cobalt.

Example 3 comprises the apparatus of Example 1, wherein the ferromagnetic layer comprises iron.

Example 4 comprises the apparatus of Example 1, wherein the ferromagnetic layer comprises cobalt, iron, and boron.

Example 5 comprises the apparatus of Example 1, wherein the ferromagnetic layer comprises cobalt and iron.

Example 6 comprises the apparatus of Example 1, wherein a thickness of the ferromagnetic layer is in the range of 0.5-1.5 nanometers.

Example 7 comprises the apparatus of any one of Examples 2-6, wherein the oxide layer further comprises magnesium.

Example 8 comprises the apparatus of any one of Examples 2-6, wherein the oxide layer further comprises aluminum.

Example 9 comprises the apparatus of any one of Examples 1-8, wherein a thickness of the oxide layer is in the range of 0.5-10 nanometers.

Example 10 comprises the apparatus of any one of Examples 1-9, wherein the first portion of the ferromagnetic layer possesses in-plane magnetic anisotropy and the second portion of the ferromagnetic layer possesses perpendicular magnetic anisotropy.

Example 11 comprises the apparatus of Example 1, further comprising: a first conductive trace positioned adjacent to the first portion of the ferromagnetic layer; a second conductive trace positioned adjacent to the magnetoelectric layer; a third conductive trace positioned adjacent to a first surface of the monolayer at a first end portion of the monolayer; a fourth conductive trace positioned adjacent to the first surface of the monolayer at a second end portion of the monolayer, the first end portion and the second end portion at opposite ends of the monolayer; a fifth conductive trace positioned adjacent to the second portion the ferromagnetic layer; and a sixth conductive trace positioned adjacent to the first surface of the monolayer and between the fourth conductive trace and the fifth conductive trace, the second portion of the ferromagnetic layer positioned between the fifth conductive trace and the sixth conductive trace.

Example 12 is an apparatus comprising: a magnetoelectric layer; a first ferromagnetic layer positioned adjacent to the magnetoelectric layer; a second ferromagnetic layer extending lengthwise along a first axis; a first layer positioned between the first ferromagnetic layer and the second ferromagnetic layer; and a monolayer extending along a second axis substantially orthogonal to the first axis, the second ferromagnetic layer positioned between the monolayer and the first layer.

Example 13 comprises the apparatus of Example 12, wherein the first layer comprises iron and oxygen.

Example 14 comprises the apparatus of Example 12, wherein the first layer comprises cobalt, iron, and oxygen.

Example 15 comprises the apparatus of Example 12, wherein the first layer comprises europium and oxygen.

Example 16 comprises the apparatus of Example 12, wherein the first layer comprises cobalt and oxygen.

Example 17 comprises the apparatus of Example 12, wherein the first layer comprises nickel, iron, and oxygen.

Example 18 comprises the apparatus of Example 12, wherein the first layer comprises yttrium, iron, and oxygen.

Example 19 comprises the apparatus of Example 12, wherein the first layer comprises magnesium, aluminum, iron, and oxygen.

Example 20 comprises the apparatus of Example 12, wherein the first layer comprises nickel, aluminum, iron, and oxygen.

Example 21 comprises the apparatus of any one of Examples 12-20, wherein a thickness of the first layer is in the range of 0.5-1.5 nanometers.

Example 22 comprises the apparatus of any one of Examples 12-21, wherein the first ferromagnetic layer comprises strontium, chromium, ruthenium, and oxygen.

Example 23 comprises the apparatus of any one of Examples 12-21, wherein the first ferromagnetic layer comprises strontium, iron, molybdenum, and oxygen.

Example 24 comprises the apparatus of any one of Examples 12-21, wherein the first ferromagnetic layer comprises cobalt.

Example 25 comprises the apparatus of any one of Examples 12-21, wherein the first ferromagnetic layer comprises iron.

Example 26 comprises the apparatus of any one of Examples 12-21, wherein the first ferromagnetic layer comprises nickel.

Example 27 comprises the apparatus of any one of Examples 12-21, wherein the first ferromagnetic layer comprises iron, cobalt, and boron.

Example 28 comprises the apparatus of any one of Examples 12-21, wherein the first ferromagnetic layer comprises iron and cobalt.

Example 29 comprises the apparatus of any one of Examples 12-21, wherein the first ferromagnetic layer comprises iron and nickel.

Example 30 comprises the apparatus of any one of Examples 12-21, wherein the first ferromagnetic layer comprises iron and oxygen.

Example 31 comprises the apparatus of any one of Examples 12-21, wherein the first ferromagnetic layer comprises lanthanum, strontium, manganese, and oxygen.

Example 32 comprises the apparatus of Example 31, further comprising iron.

Example 33 comprises the apparatus of any one of Examples 22-32, wherein a thickness of the first ferromagnetic layer is in the range of 1-50 nanometers.

Example 34 comprises the apparatus of any one of Examples 12-33, wherein the second ferromagnetic layer comprises cobalt.

Example 35 comprises the apparatus of any one of Examples 12-33, wherein the second ferromagnetic layer comprises iron.

Example 36 comprises the apparatus of any one of Examples 12-33, wherein the second ferromagnetic layer comprises iron, cobalt, and boron.

Example 37 comprises the apparatus of any one of Examples 12-33, wherein the second ferromagnetic layer comprises iron and cobalt.

Example 38 comprises the apparatus of any one of Examples 34-37, further comprising an oxide layer positioned between the monolayer and the second ferromagnetic layer, the oxide layer comprising oxygen and magnesium.

Example 39 comprises the apparatus of any one of Examples 34-37, further comprising an oxide layer positioned between the monolayer and the second ferromagnetic layer, the oxide layer comprising oxygen and aluminum.

Example 40 comprises the apparatus of any one of Examples 12-33, wherein the second ferromagnetic layer comprises a stack of one or more first sub-layers comprising cobalt alternating with one or more second sub-layers comprising platinum.

Example 41 comprises the apparatus of Example 40, wherein a thickness of individual of the first sub-layers and individual of the second sub-layers is in the range of 0.5-1.5 nanometers.

Example 42 comprises the apparatus of any one of Examples 12-33, wherein the second ferromagnetic layer comprises iron, phosphorous, and sulfur.

Example 43 comprises the apparatus of any one of Examples 12-33, wherein the second ferromagnetic layer comprises chromium, germanium, and tellurium.

Example 44 comprises the apparatus of any one of Examples 12-33, wherein the second ferromagnetic layer comprises chromium and iodine.

Example 45 comprises the apparatus of any one of Examples 12-33, wherein the second ferromagnetic layer comprises manganese, phosphorous, and sulfur.

Example 46 comprises the apparatus of any one of Examples 12-33, wherein the second ferromagnetic layer comprises iron, germanium, and tellurium.

Example 47 comprises the apparatus of any one of Examples 12-33, wherein the second ferromagnetic layer comprises iron, phosphorous, and sulfur.

Example 48 comprises the apparatus of any one of Examples 42-47, wherein a thickness of the second ferromagnetic layer is about 0.5 nanometers or less.

Example 49 comprises the apparatus of any one of Examples 42-47, wherein a thickness of the second ferromagnetic layer is about 50 nanometers or more.

Example 50 comprises the apparatus of any one of Examples 12-49, wherein the first ferromagnetic layer possesses in-plane magnetic anisotropy and the second ferromagnetic layer possesses perpendicular magnetic anisotropy.

Example 51 comprises the apparatus of any one of Examples 12-50, further comprising: a first conductive trace positioned adjacent to the first ferromagnetic layer, the first ferromagnetic layer positioned between the magnetoelectric layer and the first conductive trace; a second conductive trace positioned adjacent to the magnetoelectric layer, the magnetoelectric layer positioned between the first ferromagnetic layer and the second conductive trace; a third conductive trace positioned adjacent to a first surface of the monolayer at a first end portion of the monolayer; a fourth conductive trace positioned adjacent to the first surface of the first layer at a second end portion of the first layer, the first end portion and the second end portion at opposite ends of the monolayer; a fifth conductive trace positioned adjacent to the second ferromagnetic layer; and a sixth conductive trace positioned adjacent to the first surface of the first layer and between the fourth conductive trace and the fifth conductive trace.

Example 52 comprises the apparatus of any one of Examples 1-51, wherein the monolayer comprises tin and sulfur.

Example 53 comprises the apparatus of any one of Examples 1-51, wherein the monolayer comprises tin and selenium.

Example 54 comprises the apparatus of any one of Examples 1-51, wherein the monolayer comprises tin and tellurium.

Example 55 comprises the apparatus of any one of Examples 1-51, wherein the monolayer comprises tin and two of sulfur, selenium, and tellurium.

Example 56 comprises the apparatus of any one of Examples 1-51, wherein the monolayer comprises germanium and sulfur.

Example 57 comprises the apparatus of any one of Examples 1-51, wherein the monolayer comprises germanium and tellurium.

Example 58 comprises the apparatus of any one of Examples 1-51, wherein the monolayer comprises germanium and selenium.

Example 59 comprises the apparatus of any one of Examples 1-51, wherein the monolayer comprises germanium and two of sulfur, selenium, and tellurium.

Example 60 comprises the apparatus of any one of Examples 1-51, wherein the monolayer comprises tin, germanium, and one of sulfur, selenium, and tellurium.

Example 61 comprises the apparatus of any one of Examples 1-51, wherein the monolayer comprises: a transition metal; and sulfur, selenium, or tellurium.

Example 62 comprises the apparatus of Example 61, wherein the monolayer comprises tellurium.

63 comprises the apparatus of Example 61, wherein the monolayer comprises selenium.

Example 64 comprises the apparatus of Example 61, wherein the monolayer comprises sulfur.

Example 65 comprises the apparatus of any one of Examples 1-51 wherein the monolayer comprises a transition metal dichalcogenide.

Example 66 comprises the apparatus of any one of Examples 1-51 wherein the monolayer comprises a monochalcogenide.

Example 67 comprises the apparatus of any one of Examples 1-66, wherein a thickness of the monolayer is in the range of 1-15 nanometers.

Example 68 comprises the apparatus of any one of Examples 1-67 wherein the monolayer is a first monolayer, the apparatus further comprising a second monolayer comprising graphene, the second monolayer positioned adjacent to the first monolayer.

Example 69 comprises the apparatus of any one of Examples 1-68 wherein the magnetoelectric layer comprises boron, iron, and oxygen.

Example 70 comprises the apparatus of Example 69, wherein the magnetoelectric layer further comprises lanthanum.

Example 71 comprises the apparatus any one of Examples 1-68, wherein the magnetoelectric layer comprises chromium and oxygen.

Example 72 comprises the apparatus of Example 71, wherein the magnetoelectric layer further comprises boron.

Example 73 comprises the apparatus of any one of Examples 1-68, wherein the magnetoelectric layer comprises: bismuth, iron, and oxygen; or lanthanum, bismuth, iron, and oxygen.

Example 74 comprises the apparatus of Example 11 or 51, wherein the first conductive trace, the second conductive trace, the third conductive trace, the fourth conductive trace, the fifth conductive trace, and/or the sixth conductive trace comprises copper, silver, aluminum, gold, cobalt, tungsten, tantalum, or nickel.

Example 75 comprises the apparatus any one of Examples 1-74, wherein the apparatus is an integrated circuit component.

Example 76 comprises the apparatus of any one of Examples 1-74, wherein the apparatus comprises a printed circuit board and an integrated circuit component attached to the printed circuit board, the integrated circuit component comprising the monolayer and the magnetoelectric layer.

Example 77 comprises the apparatus of Example 76, wherein the apparatus further comprises one or more memories attached to the printed circuit board.

Example 78 comprises the apparatus of any one of Examples 1-77, wherein the apparatus further comprises at least one electronic transistor.

Example 79 is a method comprising: forming a first conductive trace; forming a magnetoelectric layer positioned adjacent to the first conductive trace; forming a second conductive trace; forming a ferromagnetic layer comprising a first portion and a second portion, the ferromagnetic layer extending from the first portion to the second portion along a first axis, the magnetoelectric layer positioned adjacent to the first portion of the ferromagnetic layer, the second conductive trace positioned adjacent to the second portion of the ferromagnetic layer; forming an oxide layer positioned adjacent to the second portion of the ferromagnetic layer, the oxide layer comprising oxygen; forming a monolayer extending along a second axis substantially orthogonal to the first axis, the oxide layer positioned between the monolayer and the second portion of the ferromagnetic layer; forming a third conductive trace positioned adjacent to a first surface of the monolayer at a first end portion of the monolayer; forming a fourth conductive trace positioned adjacent to the first surface of the monolayer at a second end portion of the monolayer, the second end portion of the monolayer opposite the first end portion of the monolayer; forming a fifth conductive trace positioned adjacent to the first portion of the ferromagnetic layer; and forming a sixth conductive trace positioned adjacent to the first surface of the monolayer and positioned between the fourth conductive trace and the fifth conductive trace, the second portion of the ferromagnetic layer positioned between the second conductive trace and the sixth conductive trace.

Example 80 comprises the method of Example 79, wherein the ferromagnetic layer comprises cobalt.

Example 81 comprises the method of Example 79, wherein the ferromagnetic layer comprises iron.

Example 82 comprises the method of Example 79, wherein the ferromagnetic layer comprises cobalt, iron, and boron.

Example 83 comprises the method of Example 79, wherein the ferromagnetic layer comprises cobalt and iron.

Example 84 comprises the method of any one of Examples 80-84, wherein the oxide layer further comprises magnesium.

Example 85 comprises the method of any one of Examples 80-84, wherein the oxide layer further comprises aluminum.

Example 86 comprises the method of any one of Examples 79-85, wherein the first portion of the ferromagnetic layer possesses in-plane magnetic anisotropy and the second portion of the ferromagnetic layer possesses perpendicular magnetic anisotropy.

Example 87 comprises the method of Example 79, wherein forming the first conductive trace comprises forming the first conductive trace on an integrated circuit structure.

Example 88 comprises the method of Example 87, wherein the integrated circuit structure comprises a die substrate.

Example 89 is a method comprising: forming a first conductive trace; forming a magnetoelectric layer positioned adjacent to the first conductive trace; forming a first ferromagnet, the magnetoelectric layer positioned between the first ferromagnet and the first conductive trace; forming a first layer positioned adjacent to the first ferromagnet; forming a second ferromagnet extending lengthwise along a first axis, the first layer positioned between the first ferromagnet and the second ferromagnet; forming a monolayer extending along a second axis substantially orthogonal to the first axis, the first layer positioned between the monolayer and the second ferromagnet; forming a second conductive trace, wherein the second conductive trace is positioned adjacent to the first ferromagnet; forming a third conductive trace positioned adjacent to a first surface of the monolayer at a first end portion of the monolayer; forming a fourth conductive trace positioned adjacent to the first surface of the monolayer at a second end portion of the monolayer, the second end portion of the first layer opposite the first end portion of the monolayer; forming a fifth conductive trace positioned adjacent to the second ferromagnet; and forming a sixth conductive trace positioned adjacent to the first surface of the monolayer and positioned between the third conductive trace and the fourth conductive trace.

Example 90 comprises the method of Example 89, wherein the first layer comprises iron and oxygen.

Example 91 comprises the method of Example 89, wherein the first layer comprises cobalt, iron, and oxygen.

Example 92 comprises the method of Example 89, wherein the first layer comprises europium and oxygen.

Example 93 comprises the method of Example 89, wherein the first layer comprises cobalt and oxygen.

Example 94 comprises the method of Example 89, wherein the first layer comprises nickel, iron, and oxygen.

Example 95 comprises the method of Example 89, wherein the first layer comprises yttrium, iron, and oxygen.

Example 96 comprises the method of Example 89, wherein the first layer comprises magnesium, aluminum, iron, and oxygen.

Example 97 comprises the method of Example 89, wherein the first layer comprises nickel, aluminum, iron, and oxygen.

Example 98 comprises the method of any one of Examples 89-97, wherein the first ferromagnet comprises strontium, chromium, ruthenium, and oxygen.

Example 99 comprises the method of any one of Examples 89-97, wherein the first ferromagnet comprises strontium, iron, molybdenum, and oxygen.

Example 100 comprises the method of any one of Examples 89-97, wherein the first ferromagnet comprises cobalt.

Example 101 comprises the method of any one of Examples 89-97, wherein the first ferromagnet comprises iron.

Example 102 comprises the method of any one of Examples 89-97, wherein the first ferromagnet comprises nickel.

Example 103 comprises the method of any one of Examples 89-97, wherein the first ferromagnet comprises iron, cobalt, and boron.

Example 104 comprises the method of any one of Examples 89-97, wherein the first ferromagnet comprises iron and cobalt.

Example 105 comprises the method of any one of Examples 89-97, wherein the first ferromagnet comprises iron and nickel.

Example 106 comprises the method of any one of Examples 89-97, wherein the first ferromagnet comprises iron and oxygen.

Example 107 comprises the method of any one of Examples 89-97, wherein the first ferromagnet comprises lanthanum, strontium, manganese, and oxygen.

Example 108 comprises the method of Example 107, further comprising iron.

Example 109 comprises the method of any one of Examples 89-108, wherein the second ferromagnet comprises cobalt.

Example 110 comprises the method of any one of Examples 89-108, wherein the second ferromagnet comprises iron.

Example 111 comprises the method of any one of Examples 89-108, wherein the second ferromagnet comprises iron, cobalt, and boron.

Example 112 comprises the method of any one of Examples 89-108, wherein the second ferromagnet comprises iron and cobalt.

Example 113 comprises the method of any one of Examples 109-112, further comprising forming an oxide layer positioned between the monolayer and the first layer, the oxide layer comprising oxygen and magnesium.

Example 114 comprises the method of any one of Examples 109-112, further comprising forming an oxide layer positioned between the monolayer and the first layer, the oxide layer comprising oxygen and aluminum.

Example 115 comprises the method of any one of Examples 89-108, wherein the first ferromagnet comprises a stack of one or more first sub-layers comprising cobalt alternating with one or more second sub-layers comprising platinum.

Example 116 comprises the method of Example 115, wherein a thickness of individual of the first sub-layers and individual of the second sub-layers is in the range of 0.5-1.5 nanometers.

Example 117 comprises the method of any one of Examples 89-108, wherein the second ferromagnet comprises iron, phosphorous, and sulfur.

Example 118 comprises the method of any one of Examples 89-108, wherein the second ferromagnet comprises chromium, germanium, and tellurium.

Example 119 comprises the method of any one of Examples 89-108, wherein the second ferromagnet comprises chromium and iodine.

Example 120 comprises the method of any one of Examples 89-108, wherein the second ferromagnet comprises manganese, phosphorous, and sulfur.

Example 121 comprises the method of any one of Examples 89-108, wherein the second ferromagnet comprises iron, germanium, and tellurium.

Example 122 comprises the method of any one of Examples 89-108, wherein the second ferromagnet comprises iron, phosphorous, and sulfur.

Example 123 comprises the method of any one of Examples 89-122, wherein the first ferromagnet possesses in-plane magnetic anisotropy and the second ferromagnet possesses perpendicular magnetic anisotropy.

Example 124 comprises the method of any one of Examples 79-123, wherein the monolayer comprises tin and sulfur.

Example 125 comprises the method of any one of Examples 79-123, wherein the monolayer comprises tin and selenium.

Example 126 comprises the method of any one of Examples 79-123, wherein the monolayer comprises tin and tellurium.

Example 127 comprises the method of any one of Examples 79-123, wherein the monolayer comprises tin and two of sulfur, selenium, and tellurium.

Example 128 comprises the method of any one of Examples 79-123, wherein the monolayer comprises germanium and sulfur.

Example 129 comprises the method of any one of Examples 79-123, wherein the monolayer comprises germanium and tellurium.

Example 130 comprises the method of any one of Examples 79-123, wherein the monolayer comprises germanium and selenium.

Example 131 comprises the method of any one of Examples 79-123, wherein the monolayer comprises germanium and two of sulfur, selenium, and tellurium.

Example 132 comprises the method of any one of Examples 79-123, wherein the monolayer comprises tin, germanium, and one of sulfur, selenium, and tellurium.

Example 133 comprises the method of any one of Examples 79-123, wherein the monolayer comprises: a transition metal; and sulfur, selenium, or tellurium.

Example 134 comprises the method of Example 133, wherein the monolayer comprises tellurium.

Example 135 comprises the method of Example 133, wherein the monolayer comprises selenium.

Example 136 comprises the method of Example 133, wherein the monolayer comprises sulfur.

Example 137 comprises the method of any one of Examples 79-123 wherein the monolayer comprises a transition metal dichalcogenide.

Example 138 comprises the method of any one of Examples 79-123 wherein the monolayer comprises a monochalcogenide.

Example 139 comprises the method of any one of Examples 79-138 wherein the monolayer is a first monolayer, the method further comprising a second monolayer comprising graphene, the second monolayer positioned adjacent to the first monolayer.

Example 140 comprises the method of any one of Examples 79-139 wherein the magnetoelectric layer comprises boron, iron, and oxygen.

Example 141 comprises the method of Example 140, wherein the magnetoelectric layer further comprises lanthanum.

Example 142 comprises the method any one of Examples 79-139, wherein the magnetoelectric layer comprises chromium and oxygen.

Example 143 comprises the method of Example 142, wherein the magnetoelectric layer further comprises boron.

Example 144 comprises the method of any one of Examples 79-139, wherein the magnetoelectric layer comprises: bismuth, iron, and oxygen; or lanthanum, bismuth, iron, and oxygen.

Example 145 comprises the method of any one of Examples 79-144, wherein the first conductive trace, the second conductive trace, the third conductive trace, the fourth conductive trace, the fifth conductive trace, and/or the sixth conductive trace comprises copper, silver, aluminum, gold, cobalt, tungsten, tantalum, or nickel.

Example 146 comprises the method of any one of Examples 79-145, wherein forming the first conductive trace comprises forming the first conductive trace on an integrated circuit structure.

Example 147 comprises the method of Example 146, wherein the integrated circuit structure is a die substrate.

Example 148 comprises the apparatus of Example 61, wherein the monolayer comprises tungsten and selenium.

Example 149 comprises the apparatus of Example 61, wherein the monolayer comprises tungsten and sulfur.

Example 150 comprises the apparatus of Example 133, wherein the monolayer comprises tungsten and selenium.

Example 151 comprises the apparatus of Example 133, wherein the monolayer comprises tungsten and sulfur.

1. An apparatus comprising:
a ferromagnetic layer comprising a first portion and a second portion, the ferromagnetic layer extending from the first portion to the second portion along a first axis;
a magnetoelectric layer;
a monolayer extending along a second axis substantially orthogonal to the first axis; and
an oxide layer positioned adjacent to the second portion of the ferromagnetic layer, the magnetoelectric layer positioned adjacent to the first portion of the ferromagnetic layer, the oxide layer positioned between the second portion of the ferromagnetic layer and the monolayer, the oxide layer comprising oxygen.

2. The apparatus of claim 1, wherein the ferromagnetic layer comprises cobalt or iron.

3. The apparatus of claim 1, wherein the ferromagnetic layer comprises:
cobalt, iron and boron; or
cobalt and iron.

4. The apparatus of claim 3, wherein the oxide layer further comprises magnesium or aluminum.

5. The apparatus of claim 1, wherein the monolayer comprises:
tin and sulfur;
tin and selenium;
tin and tellurium;
tin and two of sulfur, selenium, and tellurium;
germanium and sulfur;
germanium and tellurium;
germanium and selenium;
germanium and two of sulfur, selenium, and tellurium; or
tin, germanium, and one of sulfur, selenium, and tellurium.

6. The apparatus of claim 1, wherein the monolayer comprises:
a transition metal; and
sulfur, selenium, or tellurium.

7. The apparatus of claim 1, wherein the monolayer is a first monolayer, the apparatus further comprising a second monolayer comprising graphene, the second monolayer positioned adjacent to the first monolayer.

8. The apparatus of claim 1, wherein the magnetoelectric layer comprises:
boron, iron, and oxygen;
boron, iron, oxygen, and lanthanum;
chromium and oxygen;
chromium, oxygen, and boron;
bismuth, iron, and oxygen; or
lanthanum, bismuth, iron, and oxygen.

9. The apparatus of claim 1, wherein the apparatus is an integrated circuit component.

10. The apparatus of claim 1, wherein the apparatus comprises a printed circuit board and an integrated circuit component attached to the printed circuit board, the integrated circuit component comprising the monolayer and the magnetoelectric layer.

11. An apparatus comprising:
a magnetoelectric layer;
a first ferromagnetic layer positioned adjacent to the magnetoelectric layer;
a second ferromagnetic layer extending lengthwise along a first axis;
a first layer positioned between the first ferromagnetic layer and the second ferromagnetic layer; and
a monolayer extending along a second axis substantially orthogonal to the first axis, the second ferromagnetic layer positioned between the monolayer and the first layer.

12. The apparatus of claim 11, wherein the first layer comprises:
iron and oxygen;
cobalt, iron, and oxygen;
europium and oxygen;
cobalt and oxygen;
nickel, iron, and oxygen; or
yttrium, iron, and oxygen.

13. The apparatus of claim 11, wherein the first layer comprises:
magnesium, aluminum, iron, and oxygen;
nickel, aluminum, iron, and oxygen;
strontium, chromium, ruthenium, and oxygen; or
strontium, iron, molybdenum, and oxygen.

14. The apparatus of claim 11, wherein the first ferromagnetic layer comprises cobalt, iron, or nickel.

15. The apparatus of claim 11, wherein the first ferromagnetic layer comprises:
iron, cobalt, and boron;
iron and cobalt;
iron and nickel;
iron and oxygen;
lanthanum, strontium, manganese, and oxygen; or
lanthanum, strontium, manganese, oxygen, and iron.

16. The apparatus of claim 11, wherein the second ferromagnetic layer comprises cobalt or iron.

17. The apparatus of claim 11, wherein the second ferromagnetic layer comprises:
iron, cobalt, and boron; or
iron and cobalt.

18. The apparatus of claim 17, further comprising an oxide layer positioned between the monolayer and the second ferromagnetic layer, the oxide layer comprising:
oxygen and magnesium; or
oxygen and aluminum.

19. The apparatus of claim 11, wherein the second ferromagnetic layer comprises a stack of one or more first sub-layers comprising cobalt alternating with one or more second sub-layers comprising platinum.

20. The apparatus of claim 11, wherein the second ferromagnetic layer comprises:
iron, phosphorous, and sulfur;
chromium, germanium, and tellurium;
comprises chromium and iodine;
manganese, phosphorous, and sulfur;
iron, germanium, and tellurium; or
iron, phosphorous, and sulfur.

21. The apparatus of claim 11, wherein the monolayer comprises:
tin and sulfur;
tin and selenium;
tin and tellurium;
tin and two of sulfur, selenium, and tellurium;
germanium and sulfur;
germanium and tellurium;
germanium and selenium;
germanium and two of sulfur, selenium, and tellurium; or
tin, germanium, and one of sulfur, selenium, and tellurium.

22. The apparatus of claim 11, wherein the monolayer comprises:
a transition metal; and
sulfur, selenium, or tellurium.

23. The apparatus of claim 11, wherein the magnetoelectric layer comprises:
boron, iron, and oxygen;
boron, iron, oxygen, and lanthanum;
chromium and oxygen;
chromium, oxygen, and boron;
bismuth, iron, and oxygen; or
lanthanum, bismuth, iron, and oxygen.

24. The apparatus of claim 11, wherein the apparatus is an integrated circuit component.

25. The apparatus of claim 11, wherein the apparatus comprises a printed circuit board and an integrated circuit component attached to the printed circuit board, the integrated circuit component comprising the monolayer and the magnetoelectric layer.
